(19) United States
(12) Patent Application Publication
(10) Pub. No.: US 2021/0252486 A1
(43) Pub. Date: Aug. 19, 2021

(54) NOVEL METHOD OF MANUFACTURE OF METAL NANOPARTICLES AND METAL SINGLE-ATOM MATERIALS ON VARIOUS SUBSTRATES AND NOVEL COMPOSITIONS

(71) Applicant: The Curators of the University of Missouri, Columbia, MO (US)

(72) Inventors: Xinhua LIANG, Rolla, MO (US); Xiaofeng WANG, Rolla, MO (US)

(21) Appl. No.: 16/972,845

(22) PCT Filed: Jun. 11, 2019
(86) PCT No.: PCT/US2019/036441

§ 371 Date: Dec. 7, 2020

Related U.S. Application Data
(60) Provisional application No. 62/688,496, filed on Jun. 22, 2018.
(60) Provisional application No. 62/688,498, filed on Jun. 22, 2018.

(51) Int. Cl. B01J 23/745; C23C 16/455; C23C 16/44; C23C 16/442; C23C 16/18; B01J 23/46; B01J 21/18; B01J 21/08; B01J 21/06; B01J 35/00; B01J 37/02

(52) U.S. Cl. CPC B01J 23/745; B01J 37/0219; C23C 16/4417; C23C 16/442; C23C 16/45555; C23C 16/18; B01J 23/462; B01J 23/464; B01J 23/466; B01J 23/468; B01J 21/185; B01J 21/08; B01J 21/063; B01J 35/0013; B01J 35/004; B01J 37/0221; B01J 37/0217; C23C 16/45544

(57) ABSTRACT

The present invention discloses a novel method and novel compositions comprising well-dispersed particulate metal materials, including metal nanoparticles and/or metal single-atom materials, on various substrates, said method comprising the use of atomic layer deposition (ALD) and optimization of the metal precursor dose time and the number of ALD cycles. Illustrative of the metals are Fe, Ni, Co, Ru, Rh, Ir, Os, Pt, Pd, and the like; and illustrative of the various substrates are carbon nanotubes (CNTs) (including multi-walled carbon nanotubes (MWCNTs), SiO₂, TiO₂, alumina, CeO₂, ZnO, ZrO₂, activated carbon, CuO, Fe₂O₃, MgO, CaO, graphene, and the like. The density of the dispersed metals on the substrates is significantly higher than the metal density

### CROSS-REFERENCE TO RELATED APPLICATIONS

This application claims priority under 35 USC § 119(e) to U.S. Provisional Patent Application Ser. Nos. 62/688,496 and 62/688,498, both filed on Jun. 22, 2018, the disclosures of which are incorporated herein by reference in their entirety.

### TECHNICAL FIELD

The present invention relates generally to the field of metal nanoparticles, and particularly to the sub-field of metal single-atom materials. More specifically, the invention relates to a novel method that uses atomic layer deposition (ALD) techniques for the preparation of new compositions comprising metal nanoparticles and/or metal single-atom materials supported on various substrates.

### BACKGROUND AND SUMMARY OF THE INVENTION

Supported metal nanostructures are used widely in a plethora of applications, especially as heterogeneous catalysts in a variety of industrial processes. The size of metal particles is a key factor in determining the performance of such catalysts. Particularly because low-coordinated metal atoms often function as the catalytically active sites, it has been reported that the specific activity per metal atom usually increases with decreasing size of the metal particles. However, the surface free energy of metals increases significantly with decreasing particle size, promoting aggregation into small clusters. It has been reported that using an appropriate support material that strongly interacts with the metal species prevents this aggregation, creating stable, finely dispersed metal clusters with high catalytic activity, an approach industry has used for a long time. Nevertheless, practical supported metal catalysts are inhomogeneous and usually consist of a mixture of sizes from nanoparticles to subnanometer clusters. Such heterogeneity not only reduces the metal atom efficiency but also frequently leads to undesired side reactions. It also makes it extremely difficult, if not impossible, to uniquely identify and control the active sites of interest. The ultimate small-size limit for metal particles is the single-atom catalyst (SAC), which contains isolated metal atoms singly dispersed on supports. It has been reported that SACs maximize the efficiency of metal atom use, which is particularly important for supported noble metal catalysts. Moreover, with well-defined and uniform single-atom dispersion, SACs offer great potential for achieving high activity and selectivity. Accordingly, metal SACs have recently attracted much attention owing to their incredible catalytic behavior and the potential to explore new catalytic mechanisms. Indeed, metal single-atom materials have recently risen to the forefront of international scientific research due to their unique properties and great potential in a variety of applications, especially in catalysis (for examples, see: Qiao, B., et al., Nature Chemistry, 3(8):634-641 (2011); Kyriakou, G., et al., Science (Washington), 335(6073):1209-1212 (2012); Deng, D., et al., Science Advances, 1(11):e1500462 (2015); Ding, K., et al., Science, 350(6257):189-192 (2015); Liu, P., et al., Science, 352(6287):797-800 (2016); Jones, J., et al., Science, 353(6295):150-154 (2016); and, Cheng, N., et al., Nature Communications, 7: Article Number 13638 (2016)).

However, single atoms are too mobile on supports since, as stated above, the surface free energy of metal increases dramatically when the metal particle size is reduced to the single-atom level (see: Qiao, B., et al., Nature Chemistry, 3(8):634-641 (2011)). Thus, the metal single-atoms sinter and aggregate easily during drying or calcination in the synthesis process. Consequently, it is a major challenge to prepare single-atom materials by traditional methods, including sol-gel and coprecipitation methods, and there is an ongoing need to discover new methods for preparation of non-aggregating metal single-atom materials on various supports.

During the past few years, some studies have focused on synthesis of single-atom materials, and several new methods have been reported. These methods include taking advantage of the unique properties of supports (e.g., photocatalysis of TiO₂ and defects of graphene) (see: Liu, P., et al., Science, 352(6287):797-800 (2016); Cheng, N., et al., Nature Communications, 7, article number 13638 (2016); Sun, S., et al., Scientific Reports, 3: Article Number 1775 (2013); Yan, H., et al., Journal of the American Chemical Society, 137(33):10484-10487 (2015); and, Chen, X., et al., Nano Energy, 32:353-358 (2017)), and enhancing the metal-support interactions (e.g., Pt—CeO₂, Pd—C₃N₄, and Au-zeolite) (see: Jones, J., et al., Science, 353(6295):150-154 (2016); Vilé, G., et al., Angewandte Chemie International Edition, 54(38):11265-11269 (2015); and, Yang, M., et al., Science, 346(6216):1498-1501 (2014)). In these methods, specific substrates are needed to be chosen, since strong interaction between metal single atoms and substrates is needed to prevent moving of single atoms on the substrates during preparation. Thereby, though most of these single-atom catalysts presented excellent catalytic performance in various applications, the specific supports used in these methods present a limitation to expand their applications. Moreover, although some reports have been published, few of them focused on synthesis and applications of transition metal (e.g., Fe, Co, Ni, and the like) single-atom materials (e.g., see: Deng, D., et al., Science Advances, 1(11):e1500462 (2015); Chen, X., et al., Nano Energy, 32:353-358 (2017); Fei, H., et al., Nature Communications, 6, article number 8668 (2015); and, Qiu, H. J., et al., Angewandte Chemie, 127(47):14237-14241 (2015)).

One embodiment of the invention herein provides a novel method for depositing well-dispersed metal nanoparticles (NPs) and single atoms on various substrates (or supports), and also provides novel compositions comprising said well-dispersed metal nanoparticles and said single atoms on said various substrates. In one aspect, the density of metals (i.e., the number of metal nanoparticles or single atoms per unit area) on the substrates achieved by this novel method is significantly higher than the metal density in previously reported methods. Stated another way, a key differentiator of this method, as compared to prior art methods, is that it provides a higher number of atoms per given area on the substrate, and, consequently, a higher density of active sites on the substrate. In this regard, while it may be difficult to determine the number of metal nanoparticles or single atoms per unit area, because of the different densities of different metal particles, the different surface areas of substrates, and the different metal loading on substrates, however, it can be stated that the metal particle size prepared by ALD is smaller (1-2 nm) than the metal particle size prepared by other methods, and the metal dispersion (70-100%) is much higher than the metal dispersion obtained by other methods (30-40%). Thus, taking Fe nanoparticles for illustration purposes, if 1 wt % Fe nanoparticles (2 nm diameter) are on a substrate with 100 m²/g of surface area, the Fe nanoparticle quantity would be about 3000 per μm². In another aspect, the novel method herein reduces aggregation, and creates stable, finely dispersed metals with well-defined and uniform dispersion and very high catalytic activity. Stated another way, the novel method herein provides stable compositions that comprise finely dispersed metals in which aggregation is reduced, and in which dispersion is well-defined and uniform; very high catalytic activity is observed in these compositions. This method comprises the use of a general strategy involving the technique known as atomic layer deposition (ALD), which is considered to be a subclass of chemical vapor deposition. It is a surface-controlled layer-by-layer gas phase coating process based on self-limiting surface reactions (e.g., see: Puurunen, R. L., Journal of Applied Physics, 97(12): Article No. 121301 (2005)). The use of ALD processes has been demonstrated to deposit highly dispersed metal nanoparticles (e.g., Pt, Ni, and Pd) on various supports (e.g., see: Z. Shang, et al., Chemical Communications, 49:10067-10069 (2013); T. D. Gould, et al., Journal of Catalysis, 303:9-15 (2013); X. Wang, et al., Journal of Nanoparticle Research, 19: Article No. 153 (2017); and, H. Yan, et al., Journal of the American Chemical Society, 137:10484-10487 (2015)), including the successful deposition of Pt and Pd single-atom catalysts on graphene (e.g., see: Sun, S., et al., Scientific Reports, 3: Article Number 1775 (2013)). In the invention disclosed herein, ALD reaction conditions were optimized, including decreasing the precursor dose time and precursor bubbler temperature, to control the amounts of precursors entering the reactor per minute in order to prepare SACs. In addition, controlling the number of ALD cycles is another important factor to prepare SACs. For the traditional ALD method, such as those reported in the foregoing publications, long dose time and more ALD cycles were used and metal formed nanoparticles instead of single atoms. In addition, previously researchers synthesized Pt and Pd single atoms on graphene via ALD through taking advantage of the near-perfect structure (i.e., few defect sites) of graphene. In contrast, in the invention disclosed herein, metal single atoms were deposited on different substrates by controlling ALD reaction conditions (e.g., dose time, precursor bubbler temperature, and ALD cycles), as is described later below. Moreover, the typical ALD process in previous publications will fully saturate the substrate surface during the ALD reactions. In contrast, in the invention disclosed herein, by controlling the precursor dose time (not fully saturated, e.g., by using diluted precursor and/or shorter precursor dose time), the size of metal nanoparticles or single atoms can be controlled, as is described later below.

In another embodiment, the novel method of the invention disclosed herein for obtaining the compositions of the invention is suitable for depositing a broad variety of metal single atoms, such as, illustratively, Fe, Ni, Co, Ru, Rh, Ir, Os, Pt, Pd, and the like. Moreover, a broad variety of suitable substrates may be used with this method, including inorganic non-metallic materials, metal oxides, carbon materials, and the like. Illustrative of the broad variety of suitable substrates of the invention are carbon nanotubes (CNTs) (including multi-walled carbon nanotubes (MWCNTs)), SiO₂, TiO₂, alumina, CeO₂, ZnO, ZrO₂, activated carbon, CuO, Fe₂O₃, MgO, CaO, graphene, and the like.

In another embodiment, the method disclosed herein for obtaining the compositions of the invention entails using in the ALD process various suitable metal precursors as the sources of the metal nanoparticles and/or metal single-atoms. For illustration purposes, the following metal precursors are given as examples to demonstrate the broad applicability and versatility of the disclosed method. However, it is understood that these are mere examples of suitable metal precursors, and are not intended to be limiting. Thus, for example, for the ALD process to obtain Fe single atoms, Ni single atoms, or Co single atoms, ferrocene and the like, nickelocene and the like, and cobaltocene and the like may be used as precursors, respectively, along with hydrogen gas as the additional precursor. For the ALD process to obtain Ru single atoms, the following precursors may be used: 2,4-(dimethylpentadienyl)(ethylcyclopentadienyl)Ru (DER) and O₂, or tris(2,2,6,6-tetramethyl-3,5-heptanedionato)ruthenium [Ru(thd)₃] and O₂, or RuCp₂, Ru(EtCp)₂, (EtCp)Ru(Py), or (MeCp)Ru(Py), and the like, along with O₂/H₂. For the ALD process to obtain Rh single atoms, rhodium (III) acetylacetonate and the like may be used as the precursor, along with O₂ or O₂/H₂. For the ALD process to obtain Ir single atoms, any one of Ir(acac)₃, (EtCp)Ir(COD), (MeCp)Ir(CHD), or IrF₆, and the like, may be used as the precursors, along with O₂/H₂. For the ALD process to obtain Os single atoms, OsCp₂ and the like, along with O₂/H₂, may be used as the precursor.

In another embodiment, the new compositions of the invention are obtained via a general ALD strategy is disclosed to deposit well-dispersed metals, such as metal nanoparticles (NPs) and single atom metals, on various substrates. This method involves optimizing dose time of the metal precursor and the number of metal ALD cycles. In the case of metal single atoms, the formation of the single atoms was verified by various analytical methods including X-ray absorption spectroscopy (XAS) (see: FIG. 5 below) and high-angle annular dark-field scanning transmission electron microscopy (HAADF-STEM).

In another embodiment, the general ALD strategy of the invention provides new compositions comprising metal/substrate catalysts, such as metal NPs and single atom metal/substrate catalysts, that are very active in various catalytic reactions. Illustrative of these reactions is the photocatalytic degradation of methylene blue (MB). Thus, in one example, results for a representative metal/substrate (e.g., TiO₂) catalyst prepared by the ALD method herein showed that 2 cycles of metal ALD-deposited substrate catalyst presented the highest activity in the degradation of MB and had a more than six-fold enhancement of photocatalytic activity over pure anatase TiO₂ nanoparticles (NPs). In another example, another representative metal/substrate catalyst, prepared by the novel ALD method, was evaluated for CO oxidation, exhibiting activity that is more than two orders of magnitude higher than that of reported literature catalysts.

In another embodiment, the method disclosed herein, by which the new compositions of the invention are made, allows deposition of a metal onto a substrate, to provide a composition comprising a metal/substrate material, by using ALD in a suitable reactor designed for carrying out ALD, such as, illustratively, a fluidized bed reactor (FBR) or a viscous flow reactor or other flow types of reactors known in the art, wherein said method comprises one or more of the following steps (using FBR as one example of reactor): (a) obtaining a premeasured amount of a suitable metal precursor; (b) obtaining a premeasured amount of a suitable substrate; (c) making ready an excess amount of one or more suitable precursor gas; (d) degassing the substrate at a temperature ranging between about 100° C. and about 200° C., preferably at about 150° C., for a period of time ranging between about 5 hours and about 15 hours, preferably about 10 hours; (e) loading the degassed substrate into the FBR; (f) raising the temperature of the FBR to between about 100° C. and about 500° C., preferably to between about 300-400° C. (depending on the metal; e.g., for Ni ALD, a preferred temperature is about 300° C., and for Fe ALD, a preferred temperature is about 400° C.); (g) fluidizing the substrate particles in the FBR by using flowing inert gas (e.g., N₂ gas, and the like) with the gas flow rate controlled by mass flow controllers; (h) loading the metal precursor into a bubbler heated to between about 40° C. and about 280° C. (depending on the precursor), preferably at about 115° C. (or another suitable temperature depending on the metal); (i) carrying the metal precursor into the FBR by using flowing gas (e.g., N₂ gas, and the like) with the gas flow rate controlled by mass flow controllers; (j) feeding the one or more precursor gas separately into the FBR through a distributor plate to react with the metal precursor and produce the metal particles, such as metal nanoparticles or single metal atoms; (k) subjecting the FBR to vibration from vibrators or other suitable methods known in the art (e.g., mechanical stirring) to enhance the quality of particle fluidization during the ALD coating process; (l) continuing the reaction of the metal precursor and the one or more precursor gas in the FBR for a suitable dose time, and for a suitable number of cycles, to result in deposition of the metal nanoparticles or single metal atoms onto the substrate particles; (m) flushing the FBR with N₂ gas to remove unreacted metal precursor and precursor gas and any byproducts; (n) evacuating and cooling to ambient temperature; (o) obtaining the composition comprising the metal/substrate material (i.e., the material comprising the metal NPs or single metal atoms deposited onto the substrate); wherein the suitable metal precursor and the one or more precursor gas are selected to be reactive with each other to produce metal particles, such as metal NPs or single metal atoms. It is understood that, if desired, instead of using only one suitable metal precursor in the method of the invention, two or more different suitable metal precursors may be used together. Likewise, if desired, instead of using only one suitable substrate in the method of the invention, two or more different suitable substrates may be used together.

The foregoing embodiments of the invention, and additional embodiments, are described in greater detail in the Detailed Description section and the Examples section below.

All publications cited throughout this application are incorporated herein by reference in their entirety. Indeed, throughout this description, including the foregoing description of related art and cited publications, as well as any and all publications cited in what follows below, it is to be understood that any and all publicly available documents described herein, including any and all cited U.S. patents, patent applications, and non-patent publications, are specifically incorporated by reference herein in their entirety. Nonetheless, the related art and publications described herein are not intended in any way as an admission that any of the documents described therein, including pending U.S. patent applications, are prior art to embodiments of the present disclosure. Moreover, the description herein of any disadvantages associated with the described products, methods, and/or apparatus, is not intended to limit the disclosed embodiments. Indeed, embodiments of the present disclosure may include certain features of the described products, methods, and/or apparatus without suffering from their described disadvantages.

Naturally, further objects of the invention are disclosed throughout other areas of the specification, drawings, and claims.

### BRIEF DESCRIPTION OF THE DRAWINGS

FIG. 1 shows a schematic diagram of an ALD fluidized bed reactor.

FIG. 2 shows TEM/STEM analysis for Fe/MWCNTs and Fe/SiO₂ samples. (a) HRTEM image of 8c-Fe/MWCNTs sample; (b) HAADF-STEM image of 8c-Fe/MWCNTs sample; (c) HRTEM image of 10c-Fe/TiO₂ sample; (d) HRTEM image of 5c-Fe/TiO₂-6005 sample.

FIG. 3 shows Fe content of (a) Fe/MWCNTs, (b) Fe/SiO₂, and (c) Fe/TiO₂ samples versus the number of Fe ALD cycles.

FIG. 4 displays TEM image of 5c-Fe/TiO₂ sample.

FIG. 5 shows XAS analysis for Fe single atom samples. (a) Fe K-edge XANES (7.0-7.7 keV), and (b) Fourier transformed (FT) k³-weighted χ(k)-function of EXAFS spectra of Fe samples in comparison to Fe foil, FeO, and Fe₂O₃.

FIG. 6 shows electron microscopy analysis of Fe/TiO₂ sample. HRTEM images of 25c-Fe/TiO₂ sample at (a) high and (b) low magnifications; (c-e) EDX mappings of 25c-Fe/TiO₂ sample.

FIG. 7 shows photocatalytic performance of TiO₂ and Fe/TiO₂ catalysts. (a) Relative concentration of MB, and (b) apparent kinetic constants (kₐₚₚ, min⁻¹) as a function of Fe/TiO₂ catalysts with different numbers of Fe ALD cycles.

FIG. 8 shows methylene blue concentration as a function of UV irradiation time over different samples.

FIG. 9 displays characterizations of Fe/TiO₂ photocatalysts. (a) UV-visible reflectance spectra and (b) the band gap energy of TiO₂ and Fe/TiO₂ samples. (c) Raman spectra of (1) TiO₂, (2) 1c-Fe/TiO₂, (3) 2c-Fe/TiO₂, (4) 5c-Fe/TiO₂, (5) 10c-Fe/TiO₂, (6) 20c-Fe/TiO₂, and (7) 25c-Fe/TiO₂. (d) Photoluminescence spectra of TiO₂ and Fe/TiO₂ samples excited at 280 nm.

FIG. 10 displays UV-visible spectroscopic measurements and subsequent Kubelka-Munk reflection plots for TiO₂ and Fe—TiO₂ samples.

FIG. 11 shows band gap determination of uncoated TiO₂ nanoparticles and TiO₂ nanoparticles coated with different cycles of Fe ALD. Curved blue and red linear lines represent experimental and extrapolated data, respectively.

FIG. 12 shows images of TiO₂ and Fe/TiO₂ samples.

FIG. 13 shows XRD patterns of (a) TiO₂, (b) 2c-Fe/TiO₂, (c) 5c-Fe/TiO₂, (d) 10c-Fe/TiO₂, (e) 20c-Fe/TiO₂, and (f) 25c-Fe/TiO₂.

FIG. 14 displays TEM images of (a) Fe/SiO₂ catalyst and (b) Fe/SiO₂ after 4 cycles of CO oxidation reaction (the inset figure shows the size distribution of Fe NPs).

FIG. 15 shows (a) XRD patterns of (1) as-prepared Fe/SiO₂ catalyst, (2) Fe/SiO₂ after four cycles of CO oxidation reaction, and (3) Fe/SiO₂ after 300 hr of CO oxidation reaction, and (b) H₂-TPR profile of as-prepared Fe/SiO₂ sample.

FIG. 16 shows images of Fe/SiO₂ samples before and after CO oxidation reaction.

FIG. 17 shows high resolution XPS spectra of Fe (2p) for Fe/SiO₂ samples before and after CO oxidation reactions.

FIG. 18 shows XPS spectra of survey scan of Fe/SiO₂ samples before and after CO oxidation reactions.

FIG. 19 shows effect of different molar ratios of CO to O₂ on CO conversion over Fe/SiO₂ catalyst. The flow rate of CO was kept at 2 sccm, and that of O₂ was 2 sccm, 10 sccm, and 20 sccm in each run.

FIG. 20 shows comparison of Fe/SiO₂ and SiO₂ activity on CO oxidation with different CO:O₂ molar ratios of (a) 1:1, (b) 1:5, and (c) 1:10.

FIG. 21 shows (a) cycling stability test and (b) long-term stability test of Fe/SiO₂ catalyst for CO oxidation.

FIG. 22 shows Fe/SiO₂ catalyst after 300 hr of CO oxidation reaction.

FIG. 23 shows Raman spectra of (a) SiO₂, (b) as-prepared Fe/SiO₂, and (c) Fe/TiO₂ catalyst after 300 hr of reaction.

FIG. 24 displays (a) HRTEM image and (b-d) EDX mappings of Fe/SiO₂ sample after 300 hr of CO oxidation reaction.

FIG. 25 displays electron energy loss spectra (EELS) of Fe/SiO₂ sample after 300 hr of CO oxidation reaction for FIG. 24.

FIG. 26 displays a scheme of Fe nanoparticles aggregation during CO oxidation long-term stability test over Fe/SiO₂ catalyst.

### DETAILED DESCRIPTION

Before the present methods, implementations and systems are disclosed and described, it is to be understood that this invention is not limited to specific components, specific methods, specific implementation, or to particular compositions, and as such may, of course, vary. It is also to be understood that the terminology used herein is for the purpose of describing particular implementations only and is not intended to be limiting. Neither are mechanisms which have been provided to assist in understanding the disclosure meant to be limiting.

In one embodiment, disclosed herein are novel compositions comprising well-dispersed metal nanoparticles (NPs) and/or metal single atoms on various substrates. These compositions are obtained via a novel method for depositing metals on said various substrates. In one aspect, the density of the metals on the substrates achieved by this novel method is significantly higher than the metal density in previously reported methods. Stated another way, a key differentiator of this method, as compared to prior art methods, is that it provides a higher number of atoms per given surface area, and consequently, a higher density of active sites on the substrate. The method disclosed herein allows deposition of a metal onto a substrate by using ALD in a reactor designed for carrying out ALD, such as, illustratively, a fluidized bed reactor (FBR) or a viscous flow reactor or other flow types of reactors known in the art, to provide a well-dispersed metal/substrate composition of the invention, wherein said method comprises one or more of the following steps:
(a) obtaining a premeasured amount of a suitable metal precursor;
(b) obtaining a premeasured amount of a suitable substrate, wherein the weight ratio of the amount of suitable metal precursor to suitable substrate is in the range between about 0.05 and about 1, preferably between about 0.08 and 0.15;
(c) making ready an excess amount of one or more suitable precursor gas;
(d) degassing the substrate at a temperature ranging between about 100° C. and about 200° C., preferably at about 150° C., for a period of time ranging between about 5 hours and about 15 hours, preferably about 10 hours;
(e) loading the degassed substrate into the FBR;
(f) raising the temperature of the FBR to between about 100° C. and about 500° C., preferably to about 400° C.;
(g) fluidizing the substrate particles in the FBR by using flowing N₂ gas with the gas flow rate controlled by mass flow controllers;
(h) loading the metal precursor into a bubbler heated to between about 40° C. and about 280° C., preferably at about 115° C. (depending on the metal);
(i) carrying the metal precursor particles into the FBR by using flowing N₂ gas with the gas flow rate controlled by mass flow controllers;
(j) feeding the one or more precursor gas separately into the FBR through a distributor plate to react with the metal precursor and produce the metal particles, such as metal NPs or single metal atoms, such that the precursor gas flow rate ranges between about 3 sccm and about 30 sccm, preferably between about 6 sccm and about 10 sccm;
(k) subjecting the FBR to vibration from vibrators or suitable other methods known in the art (e.g., stirring) to enhance particle fluidization during the ALD coating process;
(l) continuing the reaction of the metal precursor and the one or more precursor gas in the FBR for a suitable dose time, and for suitable number of cycles, to result in deposition of the metal NPs or single metal atoms onto the substrate particles;
(m) flushing the FBR with inert gas (e.g., N₂ gas, and the like) to remove unreacted metal precursor and precursor gas and any byproducts;
(n) evacuating and cooling to ambient temperature;
(o) obtaining the well-dispersed metal/substrate composition of the invention (i.e., metal NPs or single metal atoms/substrate composition);
   wherein the suitable metal precursor and the one or more precursor gas are selected to be reactive with each other to produce metal particles, such as metal NPs or single metal atoms.

In another embodiment of the method of the invention, the metal may be selected from a broad variety of metals, illustratively including Fe, Ni, Co, Ru, Rh, Ir, Os, Pt, Pd, and the like. In another embodiment of the method of the invention, a broad variety of suitable substrates may be used in the method of the invention, including inorganic non-metallic materials, metal oxides, carbon materials, and the like, such as, illustratively, carbon nanotubes (CNTs) (including multi-walled carbon nanotubes (MWCNTs)), SiO₂, TiO₂, alumina, CeO₂, ZnO, ZrO₂, activated carbon, CuO, Fe₂O₃, MgO, CaO, graphene, and the like. In another embodiment of the method of the invention, a broad variety of suitable metal precursors may be used, such as, illustratively, ferrocene and the like, nickelocene and the like, cobaltocene and the like, respectively, along with hydrogen gas as the additional precursor; 2,4-(dimethylpentadienyl)(ethylcyclopentadienyl)Ru (DER) and O₂, or tris(2,2,6,6-tetramethyl-3,5-heptanedionato)ruthenium [Ru(thd)₃] and O₂, or RuCp₂, Ru(EtCp)₂, (EtCp)Ru(Py), or (MeCp)Ru(Py), and the like, along with O₂/H₂; rhodium (III) acetylacetonate and the like, along with O₂ or O₂/H₂; any one of Ir(acac)₃, (EtCp)Ir(COD), (MeCp)Ir(CHD), or IrF₆, and the like, along with O₂/H₂; OsCp₂ and the like, along with O₂/H₂.

It is understood that, if desired, instead of using only one suitable metal precursor in the method of the invention, two or more different suitable precursors of the same metal may be used. Also, as contemplated herein, two or more different suitable precursors of two or more different metals may be used together, in which case a composition comprising two or more well-dispersed different metals on the same substrate would be obtained. Likewise, if desired, instead of using only one suitable substrate in the method of the invention, two or more different suitable substrates may be used together, to provide a composition comprising one or more well-dispersed metal on two or more different substrates.

Another embodiment of the invention provides a general ALD strategy to prepare compositions comprising well-dispersed metal on a substrate, such as nanoparticulate metal atoms, sub-nanoparticulate metal atoms, and single metal atoms, on various substrates, via the ALD-mediated reaction of a suitable metal precursor with a precursor gas, through optimizing dose time of the metal precursor and the number of metal ALD cycles. In one aspect, the compositions obtained by the method include a higher density of well-dispersed, non-aggregated metal relative to the density of metal obtained in published methods.

While the novel technology herein has been illustrated and described in detail in the foregoing description, and in the following examples and the figures herein, the same is to be considered as illustrative and not restrictive in character. It is understood that one of ordinary skill in the art could readily make a nigh-infinite number of insubstantial changes and modifications to the above-described embodiments and that it would be impractical to attempt to describe all such embodiment variations in the present specification. Accordingly, it is understood that all changes and modifications that come within the spirit of the novel technology are desired to be protected.

### EXAMPLES

The following examples further illustrate specific embodiments of the invention. However, the following examples should not be interpreted in any way to limit the invention.

EXAMPLE 1. General method for preparing metal single atoms via ALD. Generally, the following steps may be used to prepare single atoms via ALD: (a) putting certain amount of substrates ranging between about 1 g to 20 g in the reactor (e.g., FBR is used in this example for illustration); (b) fluidizing the substrate particles in the FBR by using flowing inert gas (e.g., N₂ gas) with the gas flow rate controlled by mass flow controllers ranging between about 3 sccm and about 20 sccm, preferably about 7 sccm; (c) degassing the substrate at a temperature ranging between about 100° C. and about 200° C., preferably at about 150° C., for a period of time ranging between about 5 hours and about 15 hours, preferably about 10 hours; (d) raising the temperature of the FBR to between about 100° C. and about 500° C., preferably to between about 300-400° C.; (e) loading certain amount of the metal precursor ranging between about 0.2 g and about 2 g, into a bubbler heated to between about 40° C. and about 280° C., preferably at about 115° C.; (f) carrying the metal precursor into the FBR by using flowing gas (e.g., N₂ gas) with the gas flow rate controlled by mass flow controllers ranging between about 3 sccm and about 20 sccm; (g) feeding the one or more precursor gas separately into the FBR through a distributor plate to react with the metal precursor and produce the metal particles, such as metal nanoparticles or single atom metal particles; (h) continuing the reaction of the metal precursor and the another precursor gas (e.g., H₂) in the FBR for a suitable dose time ranging between about 10 s and about 600 s, and for a suitable number of cycles ranging between about 1 and about 30 cycles, preferably about 5 cycles, to result in deposition of the metal nanoparticles or single metal atoms onto the substrate particles; (i) flushing the FBR with inert gas (e.g., N₂ gas) to remove unreacted metal precursor and precursor gas and any byproducts for a certain time ranging about 60 s and 1200 s; (j) evacuating and cooling to ambient temperature; (k) obtaining the composition comprising the metal/substrate material (i.e., the material comprising the metal NPs or single metal atoms deposited onto the substrate).

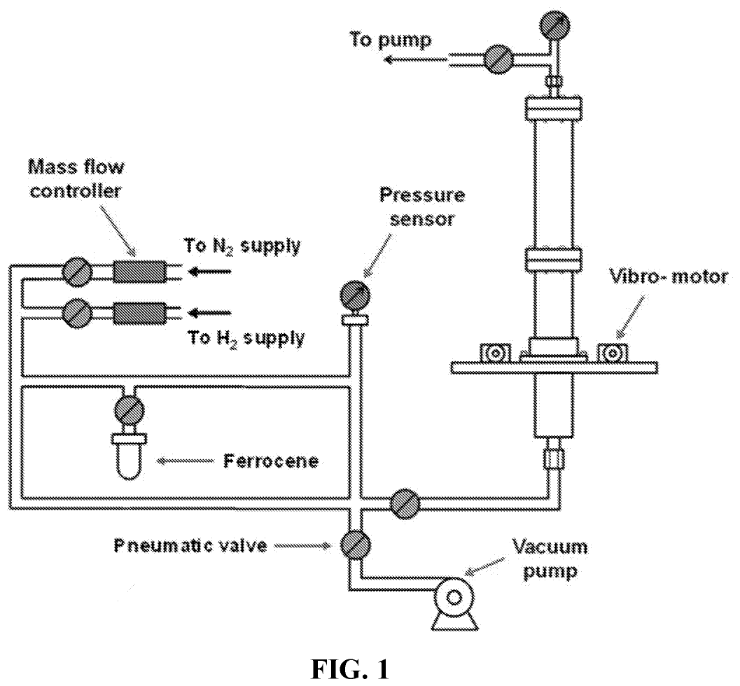

EXAMPLE 2. Methods. Preparation of Catalysts. The following is a representative, non-limiting example using Fe as the metal being deposited on three different supports. Fe single atoms were deposited on MWCNTs (US Nano Inc), SiO₂ NPs (20-30 nm, US Nano Inc), and TiO₂ NPs (DT 51, 100% anatase, ˜80 m²/g, Cristal Inc) by ALD using ferrocene and hydrogen (H₂, 99.9%, Airgas) as precursors in a fluidized bed reactor, as schematically shown in FIG. 1. The reactor was described in detail elsewhere in the literature (see: Liang, X., et al., ACS Applied Materials and Interfaces, 1(9):1988-1995 (2009); Wang, X., et al., Journal of Environmental Chemical Engineering, 4(4):3767-3774 (2016)). All the chemicals were used as received without any treatment. For a typical cycle, 5 g of substrate were loaded into the reactor. The reaction temperature was 400° C. Before a reaction, the substrates were degassed at 150° C. for 10 hr. During the ALD process, the solid ferrocene (˜0.2 g) was loaded into a heated bubbler (115° C.) and carried by nitrogen (N₂, 99.9% Airgas) into the reactor. Fe(Cp)₂ and H₂ were fed separately through a distributor plate. The particle substrates were fully fluidized with the gas flow rate controlled by mass flow controllers. The reactor was also subjected to vibration from vibrators to improve the quality of particle fluidization during the ALD coating process (see: Patel, R. L., et al., Ceramics International, 41(2):2240-2246 (2015); Wang, X., et al., Catalysis Letters, 146(12):2606-2613 (2016)). N₂ was used as flush gas to remove unreacted precursors and any byproducts during the reaction. A typical coating cycle involved the following steps: ferrocene dose, N₂ purge, evacuation; H₂ dose, N₂ purge, evacuation.

EXAMPLE 3. Characterization. The Fe mass fractions of prepared Fe samples with different Fe ALD cycles were measured by ICP-AES. The crystal structure of TiO₂ was detected by XRD. The Fe supported on MWCNTs, SiO₂, and TiO₂ NPs were directly observed by FEI Tecnai F30 HRTEM. HAADF-STEM analysis was performed by Nion UltraSTEM 100. XAS was applied to verify the composition of Fe on the TiO₂ nanoparticles. Raman spectra of TiO₂ and Fe/TiO₂ samples were obtained using a Horiba-Jobin Yvon LabRam spectrometer. The PL spectra were recorded with a HORIBA FL3-22 spectrometer (HORIBA, Edison, N.J.) to investigate the recombination of photo-generated e⁻/h⁺ pairs in the samples. UV-visible DRS of Fe/TiO₂ samples were obtained with a UV-visible spectrophotometer (Varian Cary 5) and BaSO₄ was used as an absorbance standard in the UV-visible absorbance experiment. The details of characterization are as follows:

XRD analysis. The crystal structure of TiO₂ and Fe/TiO₂ samples was detected by X-ray diffraction (XRD) with filtered Cu Kα radiation (λ=1.5406 Å). The scanning range was 2θ from 20° to 80°, with a scanning rate of 0.025°/s. The Scherrer equation was applied to estimate the average crystallite sizes of TiO₂ and Fe/TiO₂ samples:

$$D = \frac{K λ}{B cos θ} ,$$

where B is the half-height width of the diffraction peak of anatase, K=0.89 is a coefficient, 0 is the diffraction angle, λ is the X-ray wavelength corresponding to the Cu Kα irradiation (1.5406 Å) and D is the average crystallite size of the powder sample.

Raman analysis. Raman spectra of TiO₂ and Fe/TiO₂ samples were recorded using a Horiba-Jobin Yvon LabRam spectrometer, equipped with a 17 mW He—Ne laser. Spectra were collected using a 10× objective lens over a wavenumber range of 200-1200 cm⁻¹. The reported spectra were generated from 10-20 scans of the respective wavenumber range, each taking ten seconds.

Band gap calculation. The UV-visible diffuse reflectance spectra (DRS) were used to evaluate the band gap of TiO₂ and Fe/TiO₂ samples by plotting [F(R)*hv]^{1/2} against hv, where hv is the energy of the incident photon and F(R) is the reflection in Kubelka-Munk function (see: George, S., et al., Journal of the American Chemical Society, 133(29):11270-11278 (2011)). The linear part of the curve was extrapolated to zero reflectance and the band gap energy was derived.

XAS analysis. XAS, including extended X-ray absorption fine structure spectroscopy (EXAFS) and X-ray absorption near edge structure spectroscopy (XANES), was conducted at bending magnet beamline 9-BM at the Advanced Photon Source (APS), Argonne National Laboratory. The XAS spectra were recorded in transmission mode with the ionization chamber optimized for maximum current with a linear response (see: Lei, Y., et al., Chemistry of Materials, 24(18):3525-3533 (2012)). Spectra at the Fe K edge (7.0-7.7 keV) were acquired for the 5c-Fe/TiO₂ and 5c-Fe/TiO₂-300 samples. Fe foil was used to calibrate the monochromator. Standard procedures based on Athena software were used to fit the XAS data.

EXAMPLE 4. Photocatalytic activity measurement. Methylene blue (MB) solution was used to evaluate the photocatalytic activity of TiO₂ and Fe/TiO₂ particles, as described in detail previously (see: Wang, X., Nanotechnology, 28(50): Article No. 505709 (2017)). Briefly, 0.1 g of sample was added in a 100 mL, 10 ppm MB solution in a suitable solvent, e.g., de-ionized water, and the like. First, the suspension solution was stirred in the dark for 60 min to achieve adsorption/desorption equilibrium. Then a UV lamp was used for 360 nm UV irradiation, and ˜1 mL test samples were taken from the main solution for analysis at a 664 nm wavelength at certain time intervals. The change in concentration of MB in the main solution was recorded over a period of reaction time.

EXAMPLE 5. A general ALD strategy to deposit well dispersed Fe single atoms on various substrates (e.g., MWCNTs, SiO₂, and TiO₂) is described. Through optimizing dose time of ferrocene (Fe(Cp)₂, precursor of Fe) and the number of Fe ALD cycles, Fe single atoms were deposited on different supports via Fe ALD. All prepared Fe samples are named and listed in Table 1. The formation of Fe single atoms was verified by X-ray absorption spectroscopy (XAS) and high-angle annular dark-field scanning transmission electron microscopy (HAADF-STEM). The photocatalytic activity of Fe/TiO₂ catalysts was evaluated by photocatalytic degradation of methylene blue (MB), as one application example of Fe/TiO₂. The results showed that 2 cycles of Fe ALD deposited TiO₂ catalyst presented the highest activity and had a more than six-fold enhancement of photocatalytic activity over pure anatase TiO₂ nanoparticles (NPs).

TABLE 1
Label of samples and sample description.

| | | | Ferrocene |
|---|---|---|---|
| | Label of Sample | Sample description | dose time (s) |
| 1 | 2c-Fe/MWCNTs | 2 cycles of Fe ALD on MWCNTs | 300 |
| 2 | 5c-Fe/MWCNTs | 5 cycles of Fe ALD on MWCNTs | 300 |
| 3 | 8c-Fe/MWCNTs | 8 cycles of Fe ALD on MWCNTs | 300 |
| 4 | 3c-Fe/SiO₂ | 3 cycles of Fe ALD on SiO₂ | 300 |
| 5 | 10c-Fe/SiO₂ | 10 cycles of Fe ALD on SiO₂ | 300 |
| 6 | 5c-Fe/SiO₂-600s | 5 cycles of Fe ALD on SiO₂ | 600 |
| 7 | 1c-Fe/TiO₂ | 1 cycle of Fe ALD on TiO₂ | 300 |
| 8 | 2c-Fe/TiO₂ | 2 cycles of Fe ALD on TiO₂ | 300 |
| 9 | 5c-Fe/TiO₂ | 5 cycles of Fe ALD on TiO₂ | 300 |
| 10 | 10c-Fe/TiO₂ | 10 cycles of Fe ALD on TiO₂ | 300 |
| 11 | 20c-Fe/TiO₂ | 20 cycles of Fe ALD on TiO₂ | 300 |
| 12 | 25c-Fe/TiO₂ | 25 cycles of Fe ALD on TiO₂ | 300 |

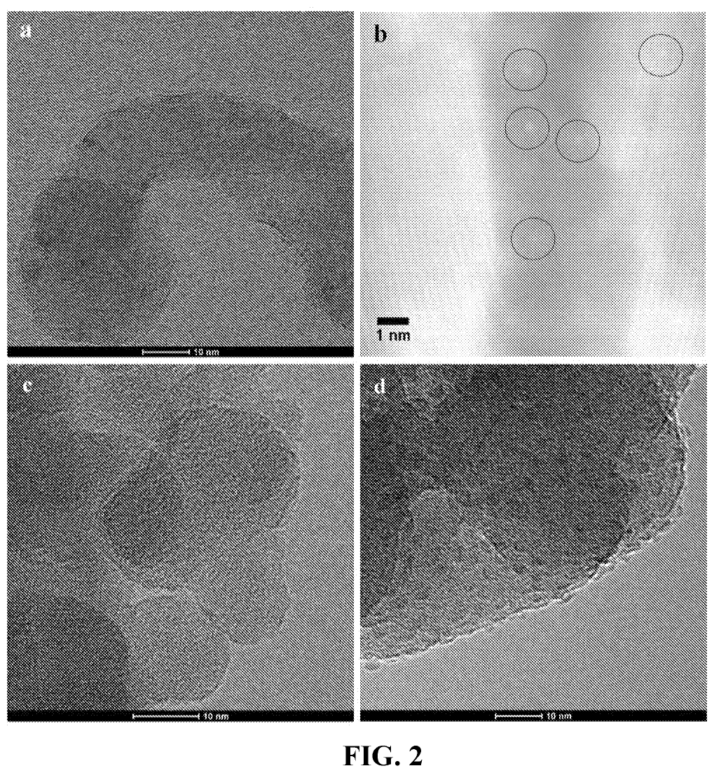

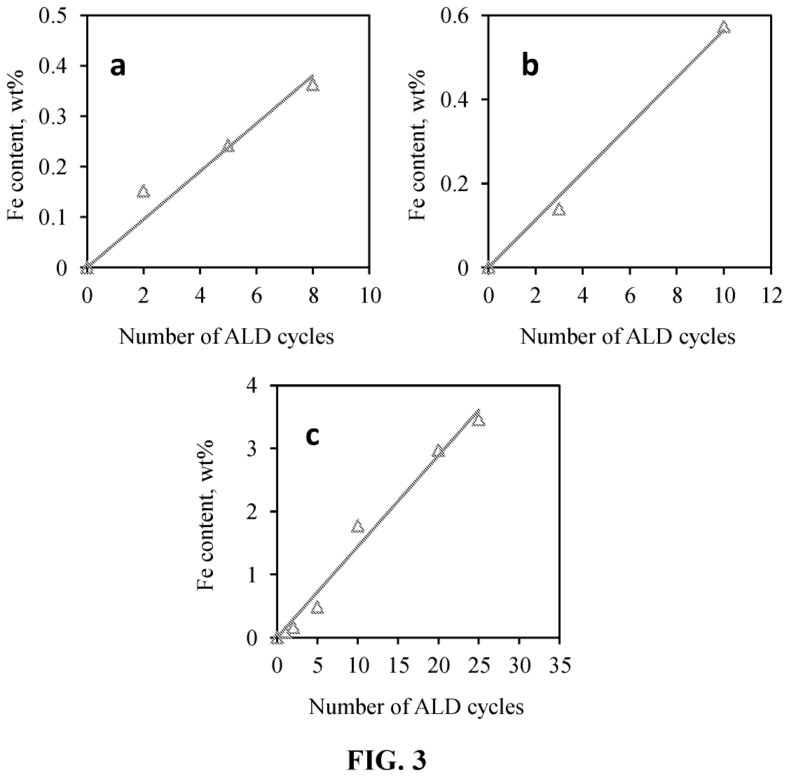

EXAMPLE 6. Results. Preparation of Fe single atoms. Firstly, different cycles (2-8 cycles) of Fe ALD were deposited on 3 g of MWCNTs in a fluidized bed reactor (FIG. 1) using ferrocene (Fe(Cp)₂) and H₂ as precursors (all samples labeled in Table 1). The dose time of Fe(Cp)₂ was 300 s. As shown in FIG. 2a, there were no Fe NPs observed through high resolution transmission electron microscopy (HRTEM) for 8c-Fe/MWCNTs with 0.36 wt. % Fe loading determined by ICP-AES (FIG. 3a). However, HAADF-STEM image presented that some bright dots of atomic size scattered on MWCNTs, highlighted by the red circles in FIG. 2b. Each dot represented an individual Fe atom, which proved that Fe single atoms were deposited on MWCNTs successfully. Then, 3 and 10 cycles of Fe ALD were applied on 3 g of SiO₂ NPs, respectively, using the same dose time (300 s) of Fe(Cp)₂. The Fe content was 0.14 wt. % and 0.57 wt. % in 3c-Fe/SiO₂ and 10c-Fe/SiO₂ samples, respectively (FIG. 3b). As presented in FIG. 2c, there was also no Fe NPs observed on SiO₂ NPs after 10 cycles of Fe ALD, which indicated the formation of Fe single atoms on SiO₂ NPs. In contrast, when the Fe(Cp)₂ dose time increased to 600 s, Fe NPs were formed on SiO₂ NPs after only 5 cycles of Fe ALD, and the average particle size of Fe NPs was around 1.5 nm, as shown in FIG. 2d. These results indicated that Fe single atoms would form with short Fe(Cp)₂ dose time, but if the dose time is extended, Fe NPs would form on the substrates instead of single atoms. It could be explained that when more Fe(Cp)₂ molecules entered the ALD reactor with longer Fe precursor does time, there was a higher possibility of the formation of Fe NPs in each Fe ALD cycle, which could be changed from Fe single atoms. So, Fe(Cp)₂ dose time played an important role in the formation of Fe single atoms during the ALD process.

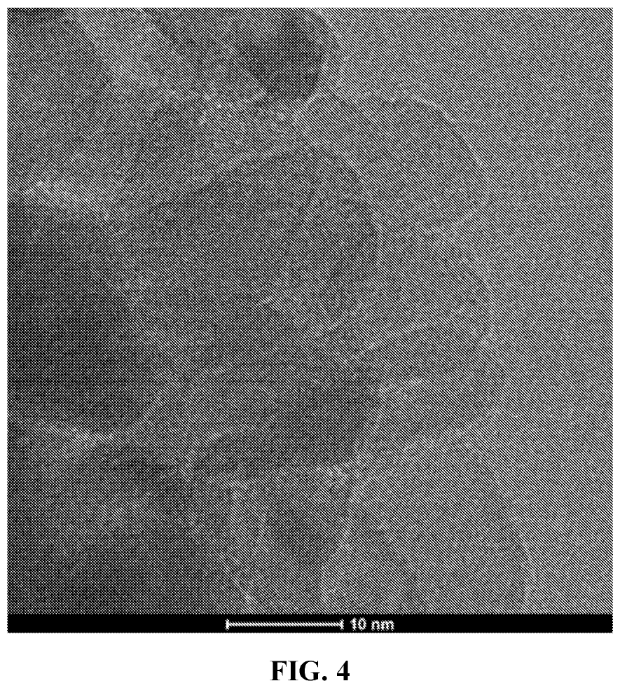

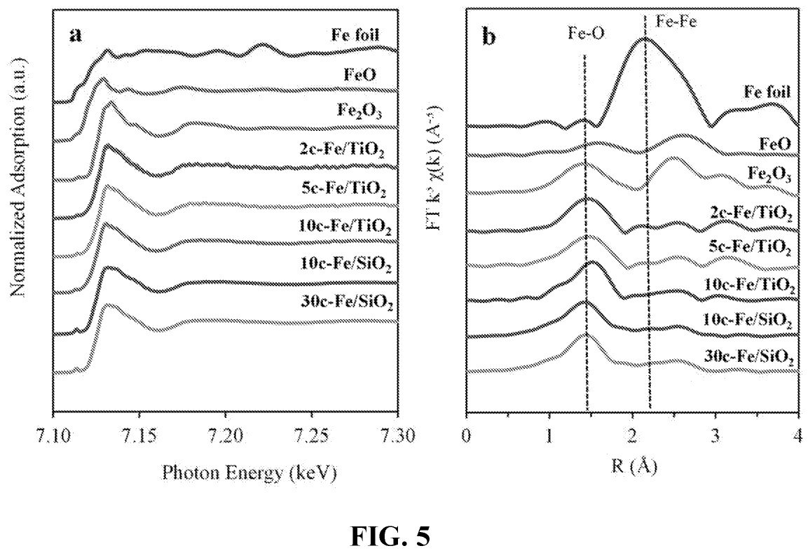

Fe single atoms were also deposited on TiO₂ via ALD to prove that Fe ALD is a universal method to synthesize Fe single-atom materials on various substrates. 1-25 cycles of Fe ALD were applied on TiO₂ NPs with 300 s of Fe(Cp)₂ dose time. As shown in FIG. 4, no Fe NPs on TiO₂ was observed in HRTEM image for 5c-Fe/TiO₂ sample with 0.49 wt. % of Fe loading (FIG. 3c). In order to verify the Fe single-atom structure of Fe/TiO₂ samples, XAS analysis was applied. As shown in FIG. 5a, the Fe K-edge of X-ray absorption near edge structure spectroscopy (XANES) in 2c-Fe/TiO₂ and 5c-Fe/TiO₂ samples exhibited a near-edge structure similar to that of the Fe₂O₃, but it is very different from those of Fe foil and FeO, indicating that Fe were single atoms and oxidized upon air exposure. After fitting and calculating, both samples were oxidized to the extent of a mixture of 90% Fe³⁺ and 10% Fe²⁺ (Table 2). Extended X-ray absorption fine structure spectroscopy (EXAFS) of the Fe K-edge shows that there was only one notable peak in the region of 1 to 2 Å from the Fe—O contribution, and no peak in the region of 2 to 3 Å from the Fe—Fe contribution, confirming the sole presence of dispersed Fe atoms in both 2c-Fe/TiO₂ and 5c-Fe/TiO₂ samples (FIG. 5b). It is believed that the Fe in 1c-Fe/TiO₂ sample, with lower Fe loading, should also be single atoms.

TABLE 2
Valence state of Fe in 2c-Fe/TiO₂ and 5c-Fe/TiO₂ samples.

| | Fe⁰ | Fe²⁺ | Fe³⁺ |
|---|---|---|---|
| 2c-Fe/TiO₂ | 0 | 12.8% | 87.2% |
| 5c-Fe/TiO₂ | 0 | 14.6% | 85.4% |

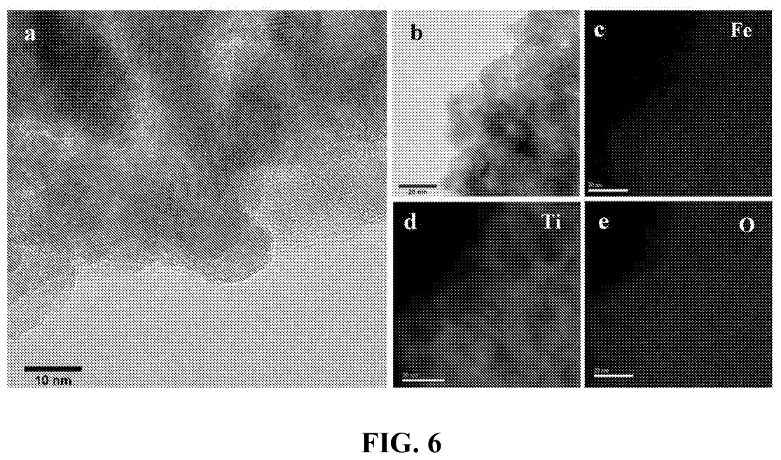

FIGS. 6a-b show that there is still no Fe NPs observed for 25c-Fe/TiO₂ samples even though the Fe loading was as high as 3.5 wt. % (FIG. 3c). However, based on element mapping (FIG. 6c-e), the signal of Fe was very strong, which indicates that Fe formed clusters or films, instead of single atoms, on the TiO₂ NPs after 25 cycles of Fe ALD. That no Fe was observed from HRTEM images could be due to the fact that the contrast between Fe and Ti was not obvious in TEM analysis, since they have very close molecular weights. It indicates that Fe formed single atoms on TiO₂ NPs first, then they became clusters or films gradually with the increase of the number of Fe ALD cycles. In the first few ALD cycles, Fe(Cp)₂ entered the ALD reactor, reacted with hydroxide groups on the TiO₂ and formed single atoms; then in the subsequent Fe ALD cycles, more Fe(Cp)₂ molecules reacted with hydroxide groups on TiO₂, and NPs or clusters formed. Thus, except for Fe(Cp)₂ dose time, controlling the number of Fe ALD cycles is another important factor to prepare Fe single atoms. It is also noted that the Fe content in the Fe/TiO₂ particles increased almost linearly with an increase in the number of ALD cycles after 25 cycles of Fe ALD, which indicated that the Fe deposition was uniform in every cycle (FIG. 3c).

ALD is a surface-controlled process based on self-limiting surface reactions. Through making use of the unique advantage of ALD, Fe single atoms deposited on MWCNTs, SiO₂, and TiO₂ by controlling the Fe(Cp)₂ dose time and the number of ALD cycles. Therefore, Fe ALD has been demonstrated to be a general method and can be used in preparation of Fe single-atom materials on various supports, including inorganic non-metallic materials, metal oxides, and carbon materials. Moreover, it was demonstrated that ALD is likewise useful in preparation of other metal single-atom materials, including Ni, Co, Ru, Rh, Ir, Os, Pt, Pd and the like, on various substrates.

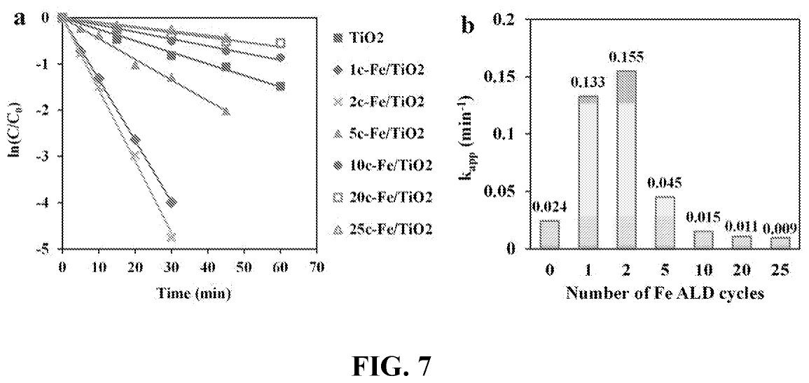

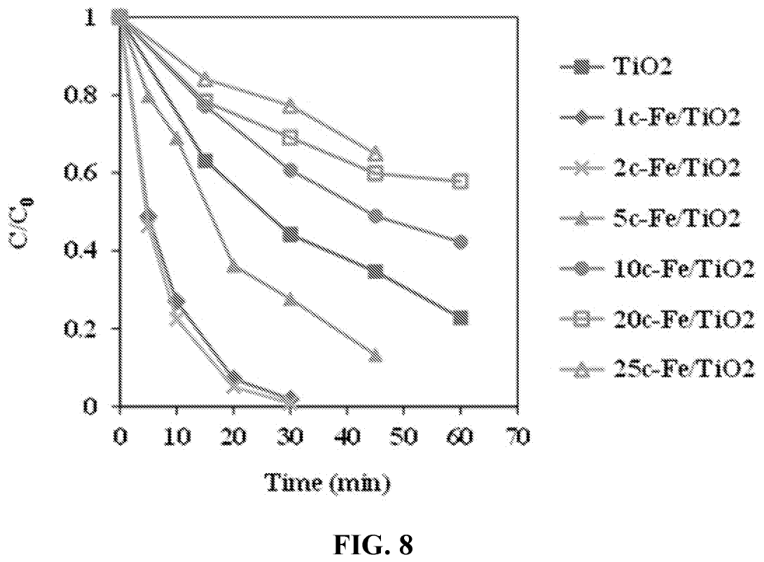

EXAMPLE 7. Photocatalytic performance of Fe/TiO₂. The photocatalytic activity of TiO₂ and Fe/TiO₂ catalysts were evaluated in terms of degradation of MB under irradiation of UV light. FIG. 7 and FIG. 8 summarize the effect of Fe ALD cycles on degradation efficiencies of MB solution as a function of irradiation. The results showed that the concentration of MB decreased by 78% over pure TiO₂ for 1 hr of UV irradiation, and the photodegradation efficiency of Fe decorated TiO₂ is higher than that of untreated TiO₂. 2c-Fe/TiO₂ was higher than that of 1c-Fe/TiO₂, but the efficiency of Fe/TiO₂ catalysts with more Fe ALD cycles (5-25) decreased dramatically and was lower than that of 1c-Fe/TiO₂ and 2c-Fe/TiO₂ catalysts. It was found that the TiO₂ catalyst containing 0.16 wt. % Fe (0.21 at. %) enhanced the photocatalytic activity the most and it was the optimal amount of Fe for degradation of MB in this study. However, the optimal Fe amount in this study was not consistent with that in the literature, which reported that the optimal Fe loading was around 0.5 at. % (see: Li, Z., et al., Journal of Hazardous Materials, 155(3):590-594 (2008); Dukes, F. M., et al., Langmuir, 28(49):16933-16940 (2012)), which could be due to the different preparation methods for Fe/TiO₂ samples. Higher optimal Fe loading (0.5 at. %) was needed via Fe doping method because some Fe ions inserted into the interior matrix of TiO₂ particles and cannot work as e⁻/h⁺ pair traps. Instead, isolated Fe atoms were only deposited on the surface of TiO₂ particles via ALD and thereby the Fe optimal content was much lower.

As shown in FIG. 7, after Fe ALD deposition, the Fe/TiO₂ samples with 1-5 Fe ALD cycles showed higher photocatalytic efficiency than TiO₂, and the apparent kinetic constants (kₐₚₚ) of 2c-Fe/TiO₂ sample reached a maximum value (0.155 min⁻¹), and its activity exceeded that of pure TiO₂ by a factor of more than six times. A literature reference (see: Liu, S., et al., Catalysis Communications, 10(6):894-899 (2009)) has reported only 1.62 times increase of photocatalytic activity as compared to the undoped TiO₂ for a similar system. In addition, Pt ALD and CeO₂ ALD have been reported to be applied for improvement of TiO₂ photoactivity, and it showed only 3 and 3.3 times increase of photocatalytic activity as compared to the pure TiO₂ at most, respectively (see: Zhou, Y., et al., Applied Catalysis B: Environmental, 101(1):54-60 (2010); Wang, X., et al., Nanotechnology, 28(50): Article No. 505709 (2017)). More importantly, Fe is much cheaper and more economical for large-scale production compared to Pt. Thus, in comparison with other methods, Fe ALD is one promising strategy to enhance Fe/TiO₂ photocatalytic performance (Table 3).

TABLE 3
Comparison of the photocatalytic activity of various Fe/TiO₂ samples.

| | Preparation | | | |
|---|---|---|---|---|
| Sample | method | Pollutant | kₐₚₚ(sample):kₐₚₚ(pure TiO₂)^{[a]} | Reference |
| 2c-Fe/TiO₂ | ALD | Methylene blue | 6.46 | This work |
| 0.5% Fe/TiO₂ | Wang et al.^{[b]} | Formaldehyde | 3 | ^{[c]} |
| 4% Fe/TiO₂ | Sol-gel method | Methyl orange | 2.0-2.5 | ^{[d]} |
| 0.25 at. % Fe/TiO₂ | Ultrasonic method | Acetone | 1.75 | ^{[e]} |
| 0.002% Fe/TiO₂ | Sol-gel method | Methyl orange | 1.62 | ^{[f]} |
| 1.8 at. % Fe/TiO₂ | Sol-gel method | Salicylic acid | 1.18 | ^{[g]} |
| 0.1% Fe/TiO₂ | Hydrothermal | Methylene blue | <1 | ^{[h]} |
| | method | | | |

^{[a]}kₐₚₚ is the apparent first order constant.
^{[b]}Wang, C. -y., et al., Chem. Commun., 2000(16): 1539-1540.
^{[c]} Dukes, F. M., et al., Langmuir, 28(49): 16933-16940 (2012).
^{[d]} Sonawane, R., et al., Materials Chemistry and Physics, 85(1): 52-57 (2004).
^{[e]} Zhou, M, et al., Journal of Hazardous Materials, 137(3): 1838-1847 (2006).
^{[f]} Liu, S., et al., Catalysis Communications, 10(6): 894-899 (2009).
^{[g]} Popa, M., et al., Journal of materials science, 44(2): 358 (2009).
^{[h]} Li, Z., et al., Journal of Hazardous Materials, 155(3): 590-594 (2008).

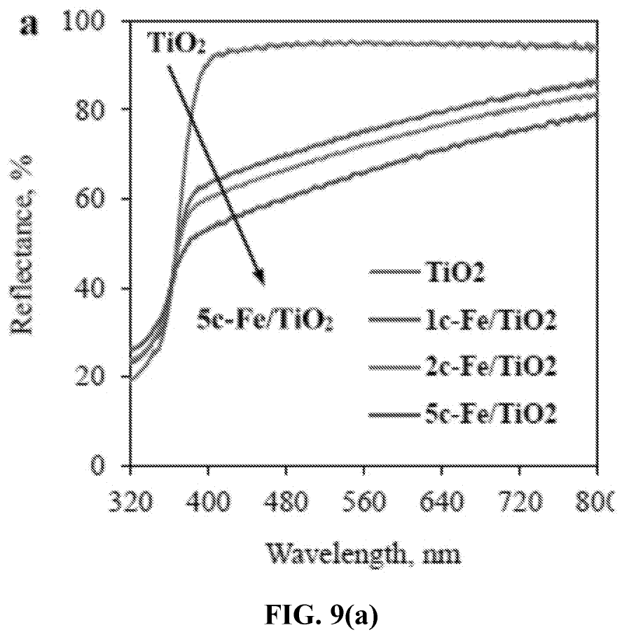

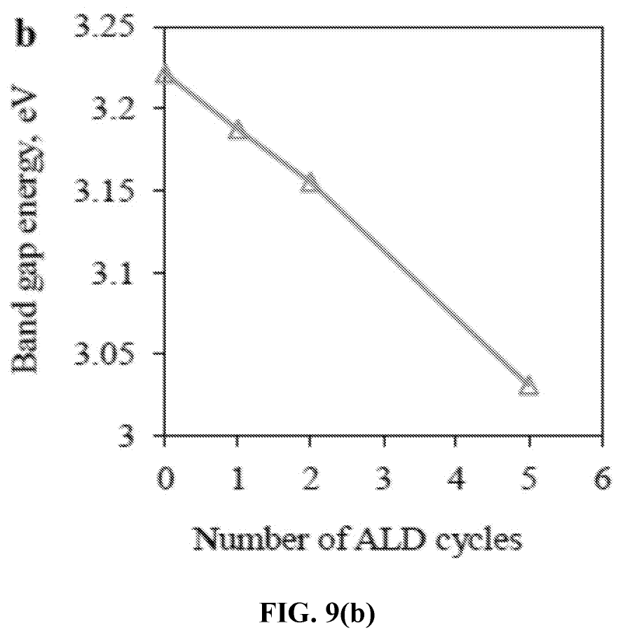

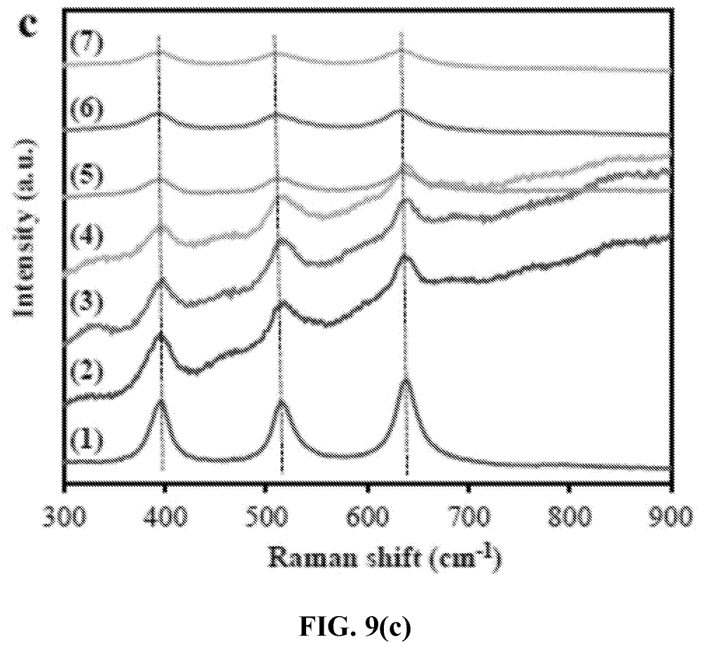

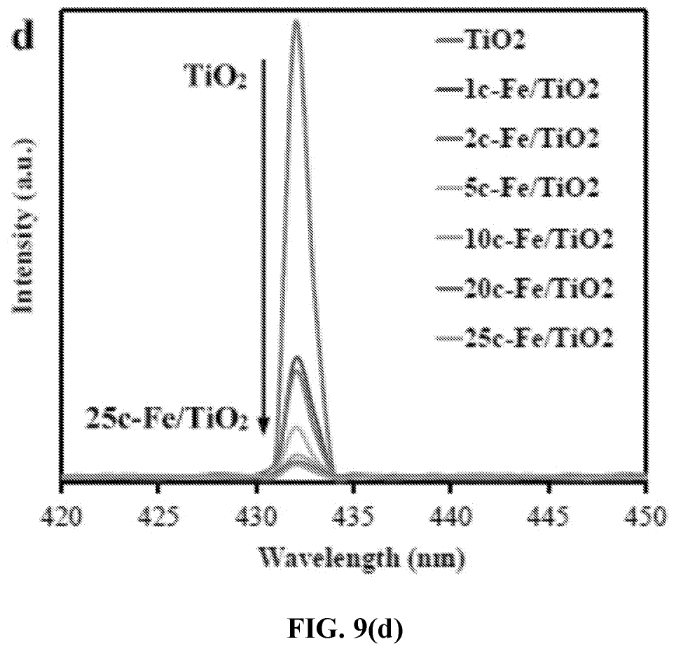

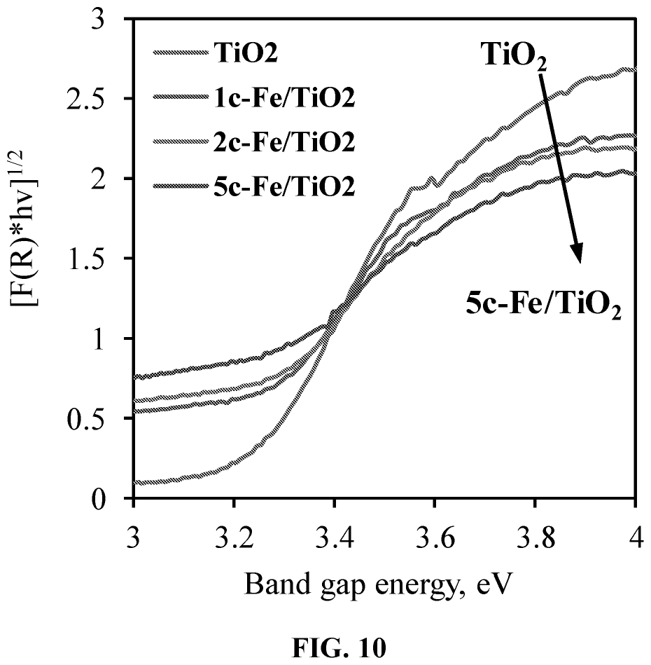

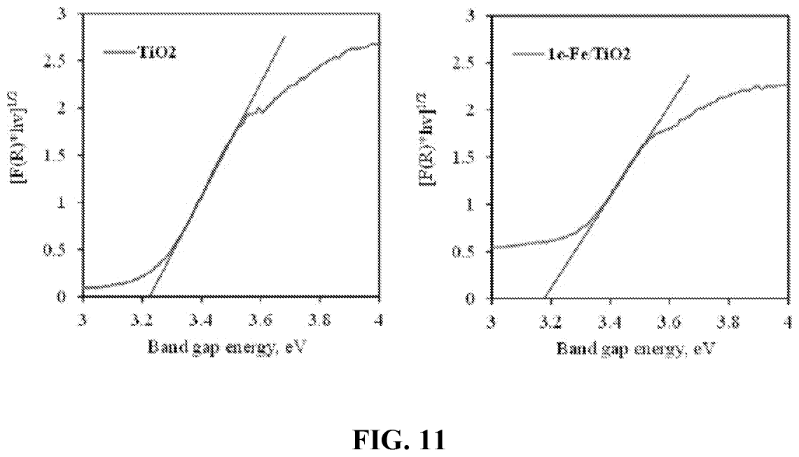

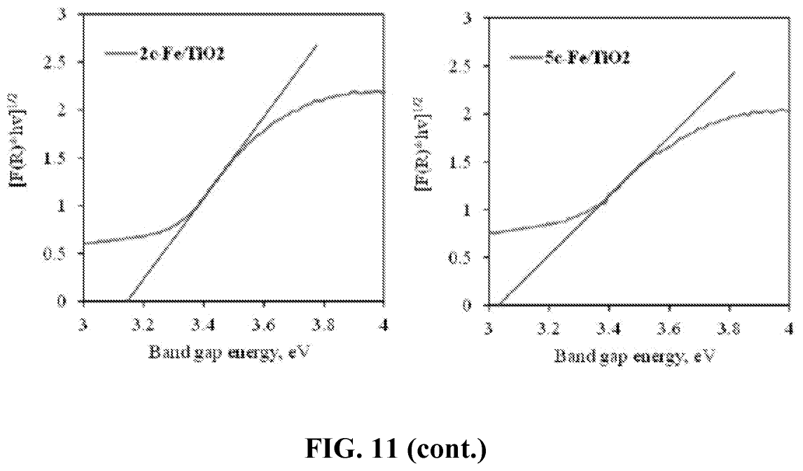

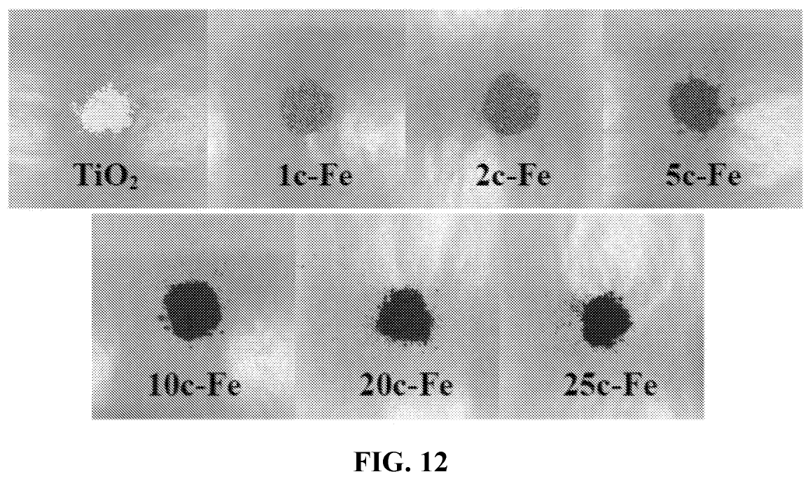

The much higher photoactivity of 2c-Fe/TiO₂ than that of TiO₂ may possibly be due to the following several factors. Firstly, Fe³⁺ ions could improve the intensity of absorption in the UV-visible light region and make a red shift in the band gap transition of 2c-Fe/TiO₂ sample. This can induce more photo-generated e⁻ and h⁺ to participate in the photocatalytic reactions (see: Zhou, M., et al., Journal of Hazardous Materials, 137(3):1838-1847 (2006)). In order to verify the hypothesis, UV-visible diffuse reflectance spectra (DRS) for pure TiO₂ and Fe/TiO₂ catalysts were recorded and the band gap was calculated. As presented in FIG. 9a, the pure TiO₂ sample showed strong photoabsorption only at wavelengths shorter than 400 nm, and the absorption edge increased with the increasing cycles of Fe ALD. The UV-visible spectroscopic measurements and subsequent Kubelka-Munk reflection plots for TiO₂ and Fe—TiO₂ samples are shown in FIG. 10 and FIG. 11. FIG. 9b shows that the band gap energy values decreased from 3.22 to 3.03 eV along with the increase of the number of Fe ALD cycles from 0 to 5. Increasing the Fe content in TiO₂ shifts the band gap energy toward longer wavelengths due to the creation of trap levels between the conduction and valence bands of TiO₂ (see: George, S., et al., Journal of the American Chemical Society, 133(29):11270-11278 (2011); Serpone, N., et al., Langmuir, 10(3):643-652 (1994)). More cycles of Fe ALD would provide more trap centers and thereby lead to a larger reduction in the band gap. At the same time, the color of the samples changed from white to black along with the increase of Fe ALD cycles (FIG. 12). It could be explained that the deposition of Fe on TiO₂ changed the absorption edge of the Fe/TiO₂ samples in the UV-visible light region, so the color of the samples altered, which is consistent with UV-vis DRS results. Similar phenomenon was observed in CeO₂-coated TiO₂ samples prepared by CeO₂ ALD (see: Wang, X., et al., Nanotechnology, 28(50): Article No. 505709 (2017)).

Secondly, Fe³⁺ can work as an e⁻/h⁺ pair traps to suppress the recombination of e⁻/h⁺ pairs and enhance lifetimes of e⁻ and h⁺, which can improve the photocatalytic activity of Fe/TiO₂ samples as well. In order to investigate the recombination rate of e⁻/h⁺ pairs in all catalysts, Raman and photoluminescence (PL) were performed. As shown in FIG. 9c, all samples showed three major Raman bands at 397, 517 and 640 cm⁻¹, which are attributed to the Raman-active modes of TiO₂ anatase phase with the symmetries of B1g, A1g, and Eg, respectively (see: Cao, T., et al., Materials Research Bulletin, 45(10):1406-1412 (2010)). Compared with the uncoated TiO₂ sample, all these three bands of Fe/TiO₂ samples were weak due to the deposition of Fe. But there is no band corresponding to Fe observed for all Fe/TiO₂ samples. It should be attributed to the low content of Fe. It is also noted that the baseline of 1c-Fe/TiO₂, 2c-Fe/TiO₂ and 5c-Fe/TiO₂ kept increasing from 300 to 1000 cm⁻¹, which resulted from fluorescence effect after Fe deposition on TiO₂ NPs. In contrast, the baseline of 10c-Fe/TiO₂, 20c-Fe/TiO₂, and 25c-Fe/TiO₂ did not increase, and it could be due to the fact that Fe formed clusters or films and prevented fluorescence phenomenon with large number of Fe ALD coating cycles, which is consistent with element mapping analysis (FIG. 6). Photoluminescence (PL) analysis of all prepared TiO₂ and Fe/TiO₂ samples was carried out to further study the fluorescence effect and recombination rate of e⁻/h⁺ pairs (FIG. 9d). The only peak at 432 nm corresponds to the reflection from anatase phase of TiO₂, and no other peak was presented corresponding to Fe in the wavelength of 300-600 nm, which could be due to the amorphous structure of Fe in the samples. But with an increase in the number of Fe ALD cycles, the PL intensity decreased greatly, which indicated that the separation efficiency of e⁻/h⁺ pairs improved for Fe/TiO₂ samples and it could result from the increase of the number of trap centers (see: Li, G., et al., Physical Chemistry Chemical Physics, 11(19):3775-3782 (2009)). In other words, more Fe³⁺ ions played an important role to separate e⁻/h⁺ pairs and reduce the recombination rate. However, with the increase of Fe content in samples, Fe³⁺ ions can serve not only as the e⁻/h⁺ traps but also as a recombination center. In this disclosure, compared to 2c-Fe/TiO₂ catalyst, the photocatalytic activity decreased greatly when the Fe concentration increased. It could be attributed to the fact that more Fe³⁺ ions played a role as e⁻/h⁺ recombination centers and improved the e⁻/h⁺ recombination rate, which led to the reduction of the kₐₚₚ values. In addition, with more Fe ALD cycles applied on TiO₂, Fe formed clusters or films, as shown in FIG. 6, and they hindered the samples to utilize UV light and could not generate enough e⁻ and h⁺ for MB degradation. Thus, the control of Fe loading plays a key role to affect the properties of Fe/TiO₂ samples.

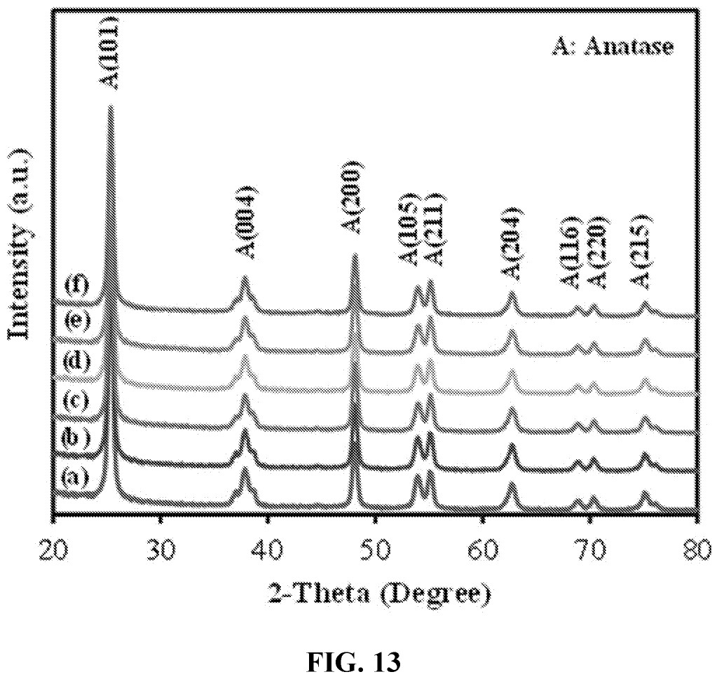

Moreover, the atomic size and uniform dispersion of Fe on TiO₂ surface is another important factor influencing photocatalytic efficiency. Fe ALD took full advantage of the high surface area of TiO₂ and Fe single atoms (˜0.2 nm) were highly dispersed on TiO₂. Thus, Fe³⁺ ions worked as e⁻/h⁺ traps as much as possible in Fe/TiO₂ samples, which leads to the fact that the recombination of e⁻ and h⁺ decreased and the photocatalytic activity improved drastically. In addition, according to XRD analysis, the TiO₂ in all samples remained anatase structure after Fe ALD and no peak corresponded to the reflections from Fe, which indicates that the crystal structure did not affect the improvement of photocatalytic activity for 2c-TiO₂ sample (FIG. 13).

Lastly, the defect sites on the surface of TiO₂ would be decorated by Fe single atoms because Fe atoms preferred to deposit and grow on defect sites during the ALD process based on ALD mechanism (see: George, S. M., Chemical Reviews, 110(1):111-131 (2010)), which can be called “defect healing”. As reported before (see: Zhang, D., Transition Metal Chemistry, 35(8):933-938 (2010)), a large surface area can enhance the photocatalytic performance of samples. However, powders with a large surface area are usually associated with large amounts of crystalline defects, which favor the recombination of photo-generated e⁻ and h⁺ leading to a poor photoactivity (see: Carp, O., et al., Progress in Solid State Chemistry, 32(1):33-177 (2004); Ohtani, B., et al., The Journal of Physical Chemistry B, 101(19):3746-3752 (1997)). In the Fe ALD process, Fe was deposited on defect sites preferentially and overcame this problem. All factors mentioned above worked collectively and resulted in improved photocatalytic activity of 2c-Fe/TiO₂.

In summary, Fe single atoms were deposited on MWCNTs, SiO₂, and TiO₂ NPs by Fe ALD. HAADF-STEM and XAS analysis proved the existence of Fe single atoms on MWCNTs and TiO₂ NPs, respectively. Ferrocene dose time and the number of ALD cycles are two dominating factors in the preparation of Fe single atoms on substrates. 2c-Fe/TiO₂ catalyst showed the highest photocatalytic activity and had a more than six-fold photocatalytic activity enhancement over pure TiO₂ for the degradation of MB due to the fact that Fe³⁺ ions played a role as e⁻/h⁺ pair traps and consequently reduced e⁻/h⁺ pair recombination rate. The uniform dispersion of Fe and the effect of “defect healing” were another two factors to enhance the activity of samples. Fe ALD is a universal strategy to prepare Fe single-atom materials on various kinds of substrates. Moreover, the ALD method has been expanded to synthesize other metal single-atom materials, without limitation regarding supports, through optimization of corresponding precursor dose time and the number of ALD cycles.

The following Examples provide additional experimental details of the disclosed invention, particularly as applied to the catalytic oxidation of carbon monoxide (CO) in the presence of metal on various supports prepared via ALD deposition. It is to be understood that oxidation of CO is but one representative example of the catalytic power of the ALD-prepared metal/supports of the invention, and that, as contemplated herein, the invention can be used to catalyze advantageously other reactions known to those skilled in the art. It is likewise understood that although in the following Examples Fe/SiO₂ is used as a representative catalyst/support, other metals/supports are contemplated herein to provide similar catalytic activity as well.

EXAMPLE 8: Highly active and stable Fe/SiO₂ catalyst synthesized by ALD for CO oxidation. CO is a strongly toxic gas. Vehicle emission is the largest anthropogenic source of CO in the United States. (e.g., see: Biabani-Ravandi, A., et al., Chemical Engineering Science, 94:237-244 (2013); N. R. Council, The ongoing challenge of managing carbon monoxide pollution in Fairbanks, Ak., National Academies Press, 2002). Among numerous methods of CO removal, catalytic oxidation is one of the most efficient approaches (e.g., see: Gac, W., Applied Catalysis B: Environmental, 75:107-117 (2007)). Since the temperature of exhaust gas produced in the vehicles is very high (400-800° C.), a long-term thermally stable catalyst is needed for such applications. Many kinds of catalysts have been reported to remove CO, including noble metal catalysts, e.g., Au (see: Li, X.-N., et al., Journal of the American Chemical Society, 136:3617-3623 (2014)) and Pt (see: Qiao, B., et al., Nature Chemistry, 3:634-641 (2011)), and transition metal oxides, e.g., CeO₂ (see: Mock, S. A., et al., Journal of Colloid and Interface Science, 466:261-267 (2016)) and Fe₂O₃ (see: Smit, G., et al., Journal of Molecular Catalysis A: Chemical, 252:103-106 (2006)). However, either high cost of noble metals or low stability limits their practical applications (e.g., see: Biabani-Ravandi, A., et al., Chemical Engineering Science, 94:237-244 (2013); Li, P., et al., Applied Catalysis B: Environmental, 43:151-162 (2003)). Fe, an earth-abundant metal, is a potential and proper catalyst for CO oxidation reaction due to its unique properties. Several theoretical investigations have demonstrated that Fe is suitable as a catalyst in the CO oxidation (e.g., see: Li, F., et al., The Journal of Physical Chemistry C, 116:2507-2514 (2012); Wu, P., et al., Physical Chemistry Chemical Physics, 17:1441-1449 (2015); Y. Tang, Y., et al., RSC Advances, 6:93985-93996 (2016)). However, few experimental studies were performed.

The novel atomic ALD process disclosed herein was used to prepare a low-cost and long-term stable Fe/SiO₂ catalyst for CO oxidation reaction. Thus, highly dispersed Fe NPs were deposited on SiO₂ NPs via ALD, as described in the foregoing. Application of the obtained Fe/SiO₂ catalyst in the oxidation of CO showed a high catalytic activity and an excellent long-term stability. It is believed that this is the first time to synthesize Fe NPs using ALD and to utilize these Fe NPs for CO oxidation reactions.

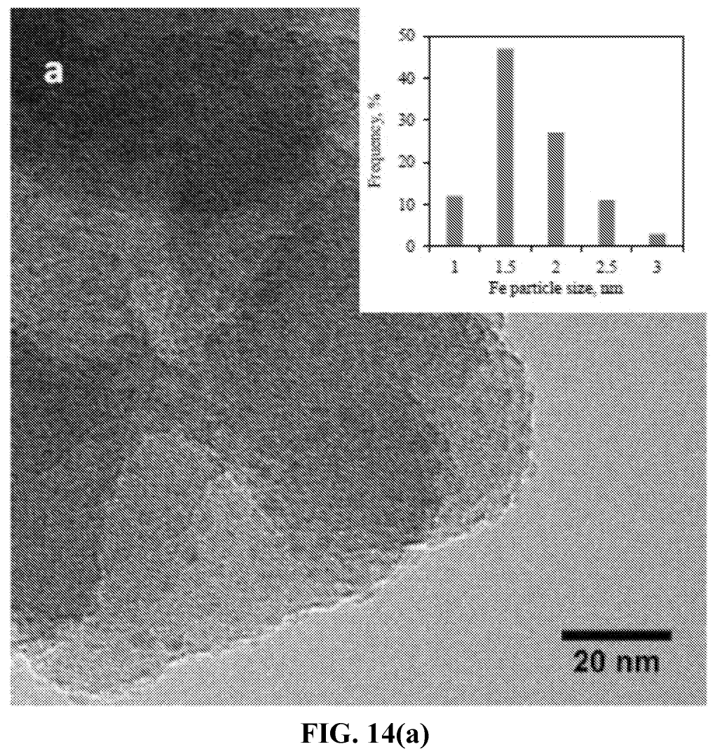

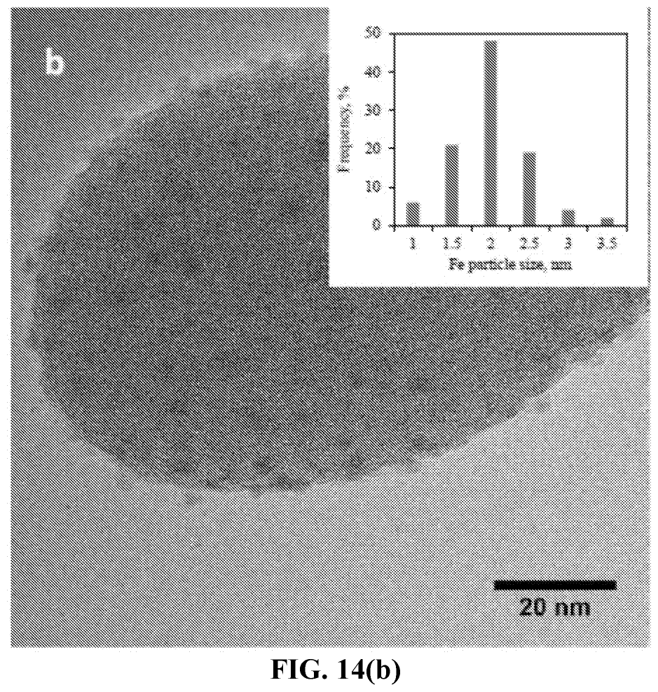

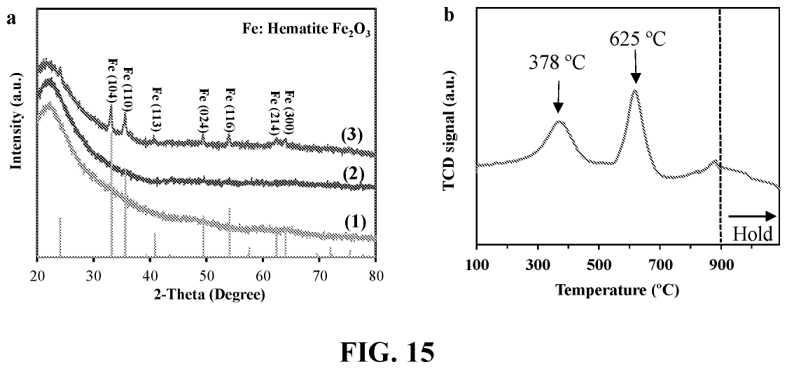

The Fe mass fraction of Fe/SiO₂ NPs was 1.98 wt. % after 5 cycles of Fe ALD and the BET surface area was 95 m²/g, which was lower than that of SiO₂ NPs (143 m²/g, Table 4). FIG. 14a shows the highly dispersed Fe NPs on the surface of SiO₂ NPs, with an average particle size of 1.5 nm. Based on XRD analysis, the sharp reflection located at the position 20=22.1° corresponded to the reflection from SiO₂ NPs, and no peaks from Fe, FeO, and Fe₂O₃ were observed (FIG. 15a, line 1). It should be due to the ultrasmall size of Fe or amorphous structure of FeO and Fe₂O₃. The reduction property of Fe/SiO₂ was determined by the H₂-TPR experiment. As shown in FIG. 15b, the first peak at around 378° C. should be attributed to the reduction of Fe₂O₃ to Fe₃O₄, and the second signal at around 625° C. should be associated with the reduction of the subsequent multiple reductions of Fe₃O₄ to FeO and Fe (see: Khoudiakov, M., et al., Applied Catalysis A: General, 291:151-161 (2005); Xi, X., et al., Journal of Environmental Chemical Engineering, 2:1011-1017 (2014)). It indicates that partial surface of some Fe NPs was oxidized in air due to its ultra-small particle size.

TABLE 4
BET surface areas of SiO₂ NPs and Fe/SiO₂ samples.

| Sample | Surface area, m²/g |
|---|---|
| SiO₂ | 143 |
| As-prepared Fe/SiO₂ | 95 |
| Fe/SiO₂ after 4 cycles of CO oxidation reaction | 97 |
| Fe/SiO₂ after 300 hr of CO oxidation reaction | 122 |

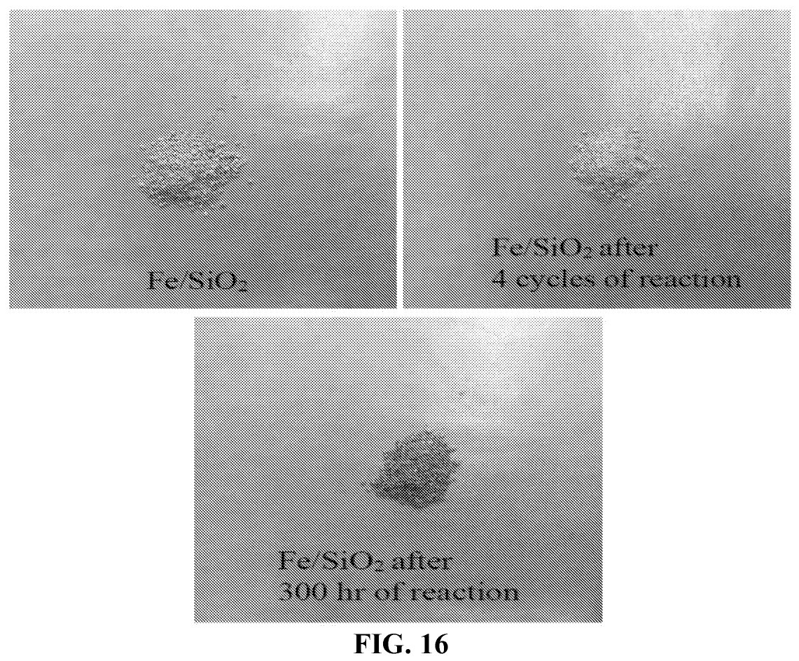

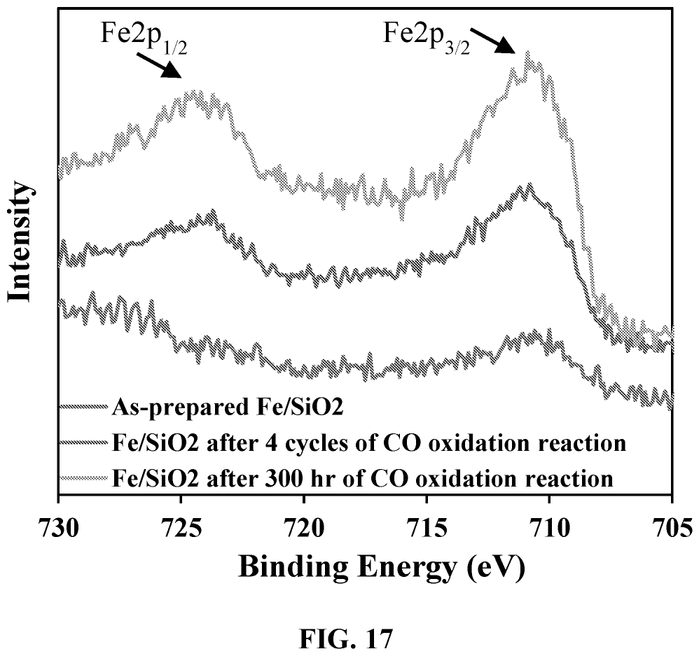

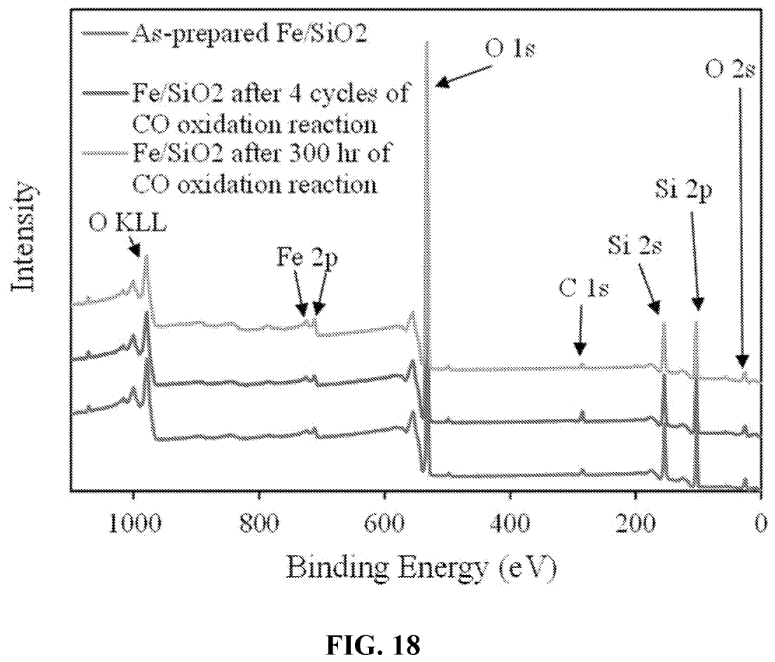

Thus, the color of Fe/SiO₂ was light yellow instead of white (FIG. 16). Similar phenomenon was observed in Pt NPs prepared by ALD (see: Wang, X., et al., Catalysis Letters, 146:2606-2613 (2016)). In order to further verify the state of Fe on SiO₂ NPs, XPS analysis was performed. As shown in FIG. 17 and FIG. 18, the peaks at 706.7, 709.6, and 710.8 eV represented Fe, FeO, and Fe₂O₃, respectively, for as-prepared Fe/SiO₂. It is consistent with TPR results.

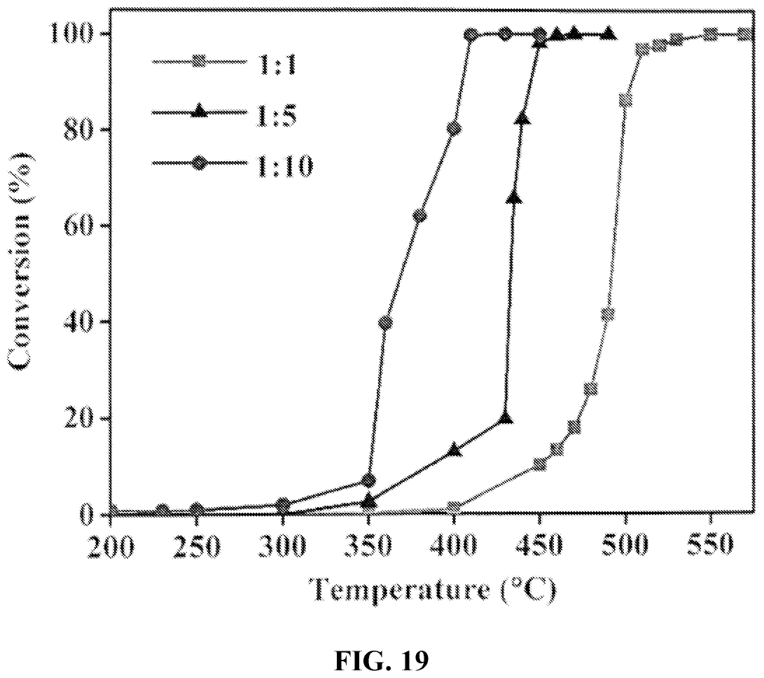

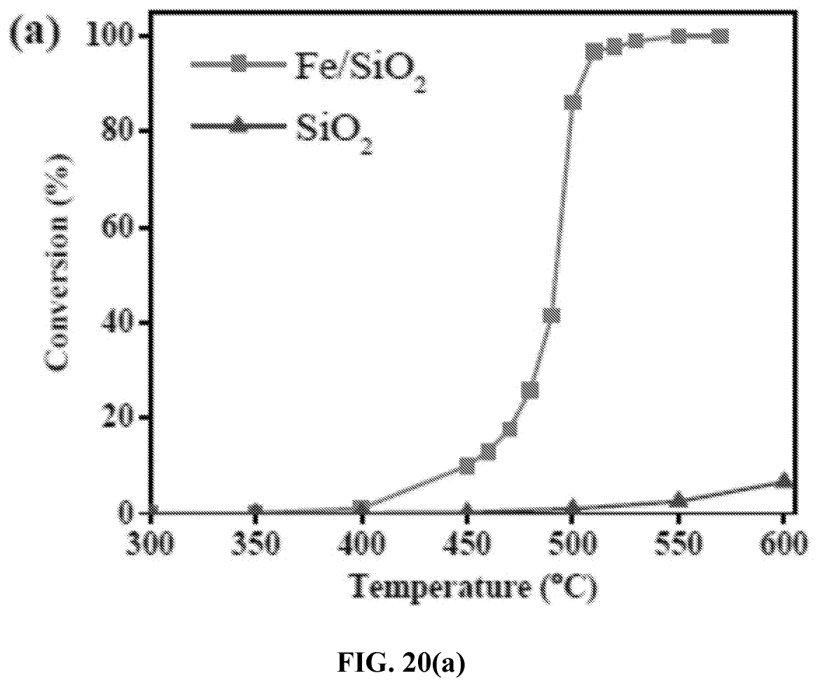

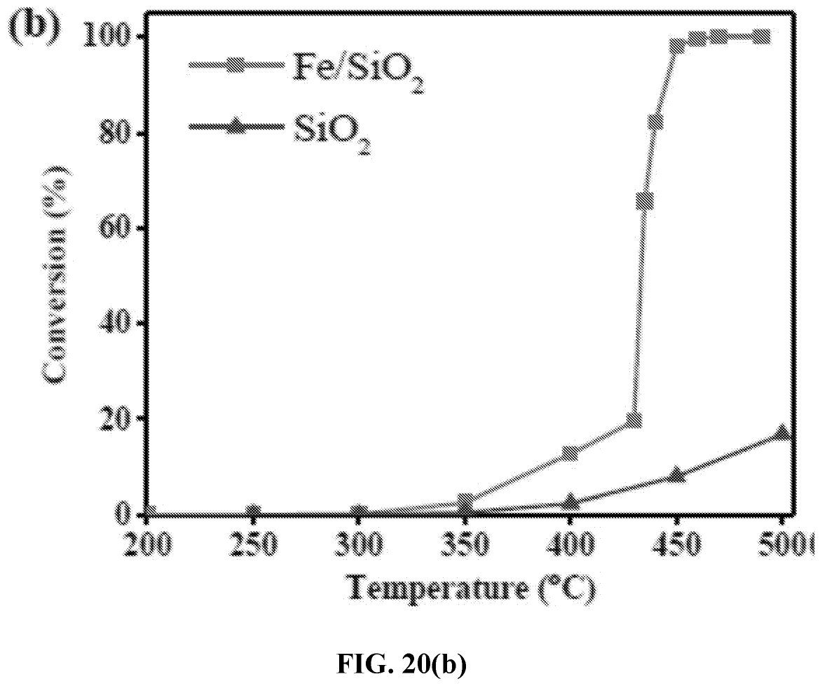

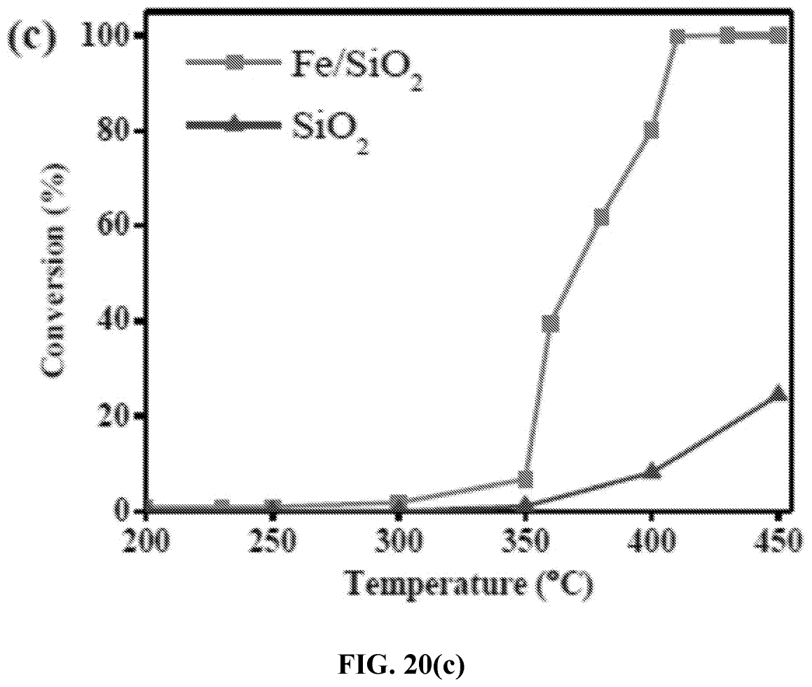

FIG. 19 compares the conversion curves of CO oxidation over Fe/SiO₂ NPs with different molar ratios of CO to 02. It is clear that with the increase of O₂ flow rate the conversion of CO oxidation reached 100% at a lower temperature. The temperatures for 100% conversion were 550° C., 470° C., and 410° C. with the CO:O₂ ratio of 1:1, 1:5, and 1:10, respectively. It indicates that high concentration of O₂ in the gas stream is helpful for catalytic oxidation of CO over Fe/SiO₂ catalysts. Compared with previously reported iron oxide catalysts, though the Fe catalysts disclosed herein were not very active at low temperature, its specific rate was more than two orders of magnitude higher than the reported values (Table 5), and thereby the Fe/SiO₂ catalyst herein is more efficient in the reaction of CO oxidation and is more suitable in practical applications. It is also noted that the reaction temperature only increased 55° C. (T₁₀₀−T₁₀) for the Fe/SiO₂ catalyst when the CO conversion increased from 10% to 100% and this number was much lower than those for other reported iron oxide catalysts, as shown in Table 5. It could be due to the high dispersion of Fe NPs on SiO₂, so the catalyst can offer more active sites. As a control, the activity of SiO₂ NPs was also evaluated by CO oxidation (FIG. 20), and the SiO₂ support did not affect the performance of Fe/SiO₂ catalyst due to its low activity.

TABLE 5
Comparison of catalytic activity for CO oxidation on different Fe-based catalysts.

| | | T₁₀^{[a]}, | T₅₀^{[b]}, | T₁₀₀^{[c]}, | Specific rate_{T100}^{[d]}, |
|---|---|---|---|---|---|
| Sample | CO:O₂ | ° C. | ° C. | ° C. | mL_{CO} g_{Fe}⁻¹s⁻¹ |
| Fe/SiO₂ | 1:10 | 355 | 370 | 410 | 33.67 |
| FeOₓ-200 ^{[e]} | 1:10 | 167 | 240 | 307 | 0.48 |
| Fe₂O₃^{[f]} | 1:10 | 210 | 290 | 420 | 0.48 |
| Fe₂O₃ nanorods ^{[g]} | 1:10 | 230 | 289 | 370 | 0.2 |
| Fe₂O₃ nanocubes^{[g]} | 1:10 | 300 | 378 | 580 | 0.2 |
| Fe₂O₃ nanotubes^{[g]} | 1:10 | 270 | 400 | 640 | 0.2 |
| Fe₂O₃ large cube ^{[h]} | 1:16 | 300 | 470 | >500 | 0.12 |
| Fe₂O₃ large rod^{[h]} | 1:16 | 190 | 240 | 280 | 0.12 |
| Fe₂O₃-430^{[i]} | 1:20 | 110 | 230 | 253 | 0.07 |

^{[a]}Temperature (° C.) for 10% CO conversion,
^{[b]}Temperature (° C.) for 50% CO conversion,
^{[c]}Temperature (° C.) for 100% CO conversion,
^{[d]}Volume per second of CO oxidized over per gram of Fe at the temperature for 100% CO conversion,
^{[e]} G. \check{S}mit, et al., Journal of Molecular Catalysis A: Chemical, 252: 103-106 (2006).
^{[f]} A. Biabani-Ravandi, et al., Chemical Engineering Journal, 219: 124-130 (2013).
^{[g]} Q. -X. Gao, et al., Catalysis Science & Technology, 1: 574-577 (2011).
^{[h]} X. Liu, et al., Catalysis Communications, 12: 530-534 (2011).
^{[i]} L. Cui, et al., Journal of Solid State Chemistry, 247: 168-172 (2017).

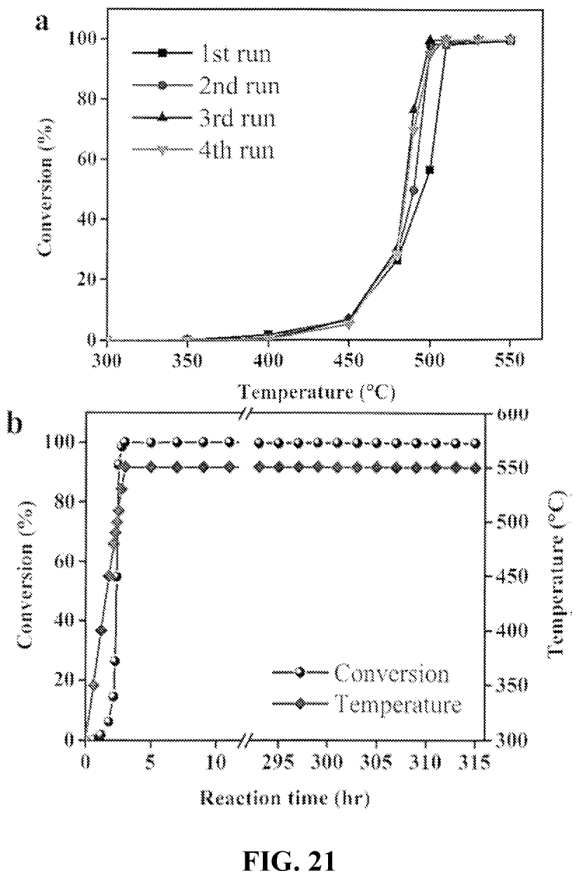

The recycle and reuse ability of catalysts is one of the key factors in practical applications. In order to evaluate the reproducibility of the Fe catalysts disclosed herein, cycling tests were performed. As shown in FIG. 21a, four cycles of reactions were applied for the Fe/SiO₂ catalyst and no noticeable difference in catalytic activity was observed with an increase in the number of reaction cycles. This demonstrates the excellent cycling stability of the Fe/SiO₂ catalyst. In addition to cycling stability tests, a long-term stability test of Fe/SiO₂ catalyst was also performed. As shown in FIG. 21b, after the CO conversion reached 100% at 550° C., the reaction was kept running for more than 300 hours and no decrease of CO conversion was observed. It indicates that the Fe/SiO₂ catalyst was extremely stable and durable under severe conditions, e.g., high temperature. Compared with other metal or metal oxide catalysts (e.g., Au, Pd, and Co₃O₄), the Fe/SiO₂ catalyst remained stable for a much longer time at higher temperature and it showed an excellent stability (Table 6). Generally, at low reaction temperature, metal nanoparticle catalysts can keep stable on the substrates and do not aggregate or sinter easily, but it is difficult to dissociate adsorbed O₂ due to lack of enough energy, which leads to deactivation of catalysts (see: Li, Y., et al., Applied Catalysis B: Environmental, 125:189-196 (2012)). On the other hand, when the reaction temperature is high, the metal particles would tend to aggregate/sinter, which also results in deactivation, though the dissociate energy is enough (see: Qi, J., et al., Energy & Environmental Science, 5:8937-8941 (2012)). In this disclosure, the Fe/SiO₂ catalyst prepared by ALD is very stable at high temperature. So, it is a potential and promising alternate for catalytic oxidation of CO exhausted from vehicles due to its high activity and outstanding stability.

TABLE 6
Comparison of long-term stability of different catalysts for CO oxidation.

| | | | Decrease of CO | |
|---|---|---|---|---|
| Sample | Temperature, ° C. | Time, hr | conversion, % | References |
| Fe/SiO₂ | 550 | >300 | 0 | This disclosure |
| Pd/graphene | 120 | 24 | 0 | Li et al.⁽³⁾ |
| Au@CeO₂ | 120 | 70 | 0 | Qi et al.⁽⁴⁾ |
| Pd—Au alloy | 80 | 10 | 2 | Xu et al.⁽⁵⁾ |
| Nanoporous Au | 30 | 24 | 4 | Xu et al.⁽⁶⁾ |
| Au—Cu/TiO₂ | 20 | 24 | 10 | Sandoval et al.⁽⁷⁾ |
| Co₃O₄ (LCP-300) | 25 | 9 | 20 | Wang et al.⁽⁸⁾ |
| Au/Zeolite Y | 25 | 70 | 27 | Chen et al.⁽⁹⁾ |
| Au—Ir/TiO₂—S | 23 | 20 | 60 | Gómez-Cortés et al.⁽¹⁰⁾ |

⁽³⁾Li, Y.; et al., Applied Catalysis B: Environmental 2012,125, 189-196.
⁽⁴⁾Qi, J.; et al., Energy & Environmental Science 2012, 5, 8937-8941.
⁽⁵⁾Xu, J.; et al., Journal of the American Chemical Society 2010,132, 10398-10406.
⁽⁶⁾Xu, C.; et al., Journal of the American Chemical Society 2007,129, 42-43.
⁽⁷⁾Sandoval, A.; et al., Applied Catalysis B: Environmental 2013,140, 363-377.
⁽⁸⁾Wang, Y. -Z.; et al., Catalysis Letters 2008, 125, 134-138.
⁽⁹⁾Chen, Y. -H.; et al., Applied Catalysis B: Environmental 2017.
⁽¹⁰⁾Gómez-Cortés, A.; et al., The Journal of Physical Chemistry C 2009, 113, 9710-9720.

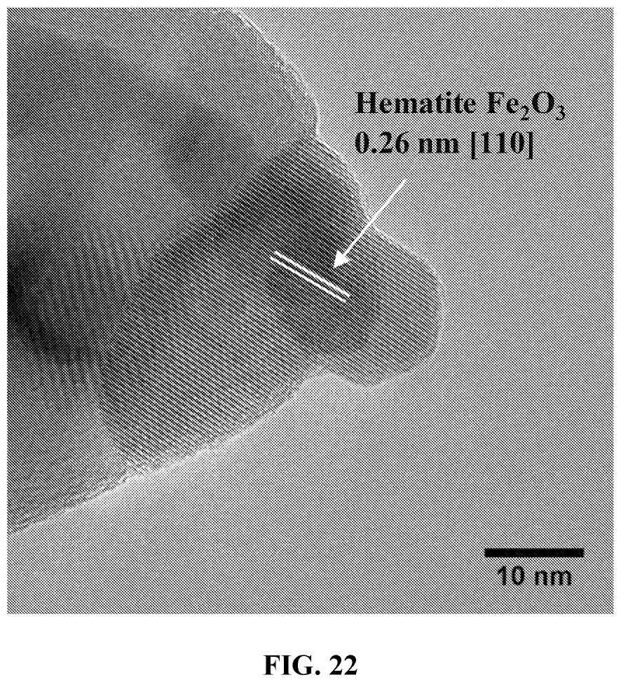

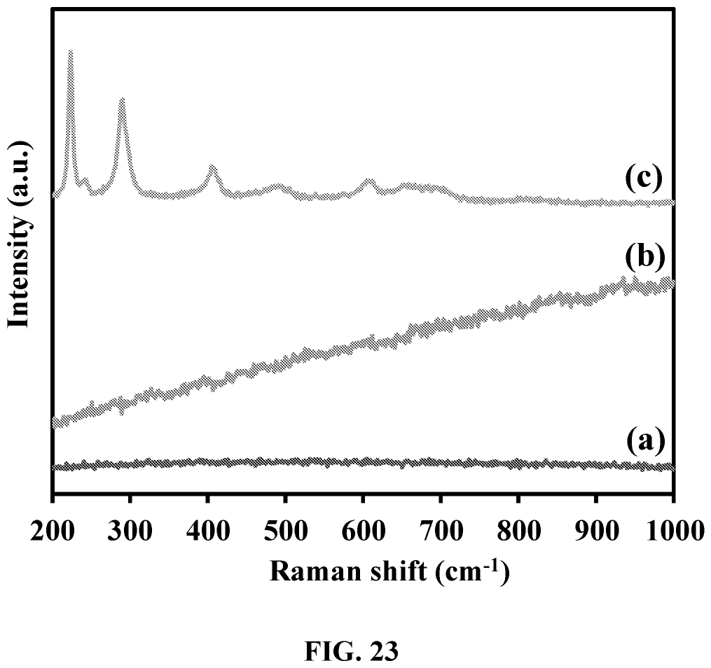

Since both metallic and oxidized Fe (Fe, FeO, and Fe₂O₃) existed in the Fe/SiO₂ catalyst disclosed herein, it was important to figure out which one played a dominating role in the CO oxidation. As shown in FIG. 16, the color of Fe/SiO₂ sample changed to dark yellow after 300 hr of reaction, which indicates that more Fe with metallic state was oxidized and changed to Fe₂O₃ during the long-term CO oxidation reaction. In order to verify this, XRD and XPS analysis for the Fe/SiO₂ samples before and after reaction were performed. The XRD pattern of Fe/SiO₂ after four cycles of reaction was similar to that of the as-prepared Fe/SiO₂ sample, and there was no peak corresponding to Fe, FeO, and Fe₂O₃ (line 2 in FIG. 15a). In contrast, the sharp reflections located at the positions 2θ=33.2°, 35.7°, 40.8°, 49.4°, 54.0°, 62.5°, and 64.2° corresponded to the reflections from (104), (110), (113), (024), (116), (214), and (300) planes of Fe₂O₃ in the hematite phase for Fe/SiO₂ after 300 hr of CO oxidation reaction (line 3 in FIG. 15a), respectively. Peak assignments were made according to JCPDS (Cards No. 01-079-1741). As presented in FIG. 17, the peak of Fe 2p_{3/2} shifted to left for both two Fe/SiO₂ samples after CO oxidation reaction and it indicates that more Fe NPs were oxidized during the reaction. Thus, the hypothesis was verified that more Fe was oxidized to Fe₂O₃ and the structure of Fe₂O₃ changed from amorphous to hematite due to the high reaction temperature (550° C.) and long reaction time (300 hr). The structure of Fe₂O₃ still remained amorphous after four cycles of reaction (line 2 in FIG. 15a), which could be attributed to the relatively short reaction time (˜10 hr). In addition, as shown in FIG. 22, the particle size of Fe NPs became large after 300 hr of CO oxidation reaction and the lattice fringes were observed in the TEM image. The lattice fringe of 0.26 nm corresponds to the (110) planes of hematite Fe₂O₃ (see: Wang, W.-W., et al., Journal of Nanoparticle Research, 9:419-426 (2007)). In contrast, the Fe NPs were still highly dispersed on SiO₂ after 4 cycles of CO oxidation reaction though the Fe average particle size increased to 1.8 nm (FIG. 14b). Raman analysis was also performed and the Fe/SiO₂ sample after 300 hr reaction showed three major Raman bands at 225, 291, and 410 cm-1, which are ascribed to the Raman-active modes of Fe₂O₃ hematite phase (FIG. 23) (see: De Faria, D., et al., Journal of Raman Spectroscopy, 28:873-878 (1997)). Both TEM and Raman analysis are consistent with XRD and XPS results.

Therefore, Fe₂O₃ was the dominate factor in the Fe/SiO₂ sample to oxidize CO to CO₂, since the conversion still remained 100% after 300 hr reaction, though more Fe changed to Fe₂O₃ during the long-term reaction. Generally, the catalytic CO oxidation over Fe₂O₃ can be divided into two steps. Firstly, Fe₂O₃ loses one oxygen atom and catalyzes CO to form CO₂, then the produced FeO is oxidized by O₂ soon (see: Li, P., et al., Applied Catalysis B: Environmental, 43:151-162 (2003)). When the concentration of O₂ in the gas stream was high, more O₂ could be used for FeO oxidation and more Fe₂O₃ would catalyze CO oxidation. Thus, 100% of CO conversion reached at a relatively low temperature with the CO:O₂ ratio of 1:10, as shown in FIG. 19.

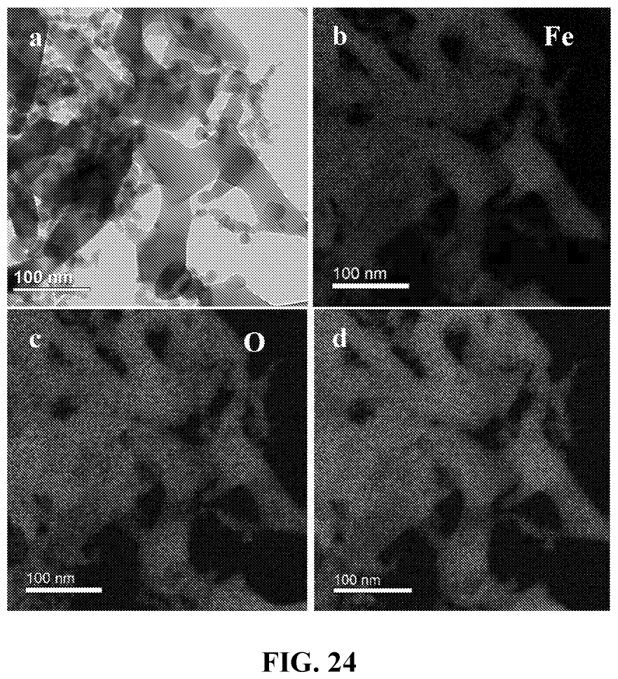

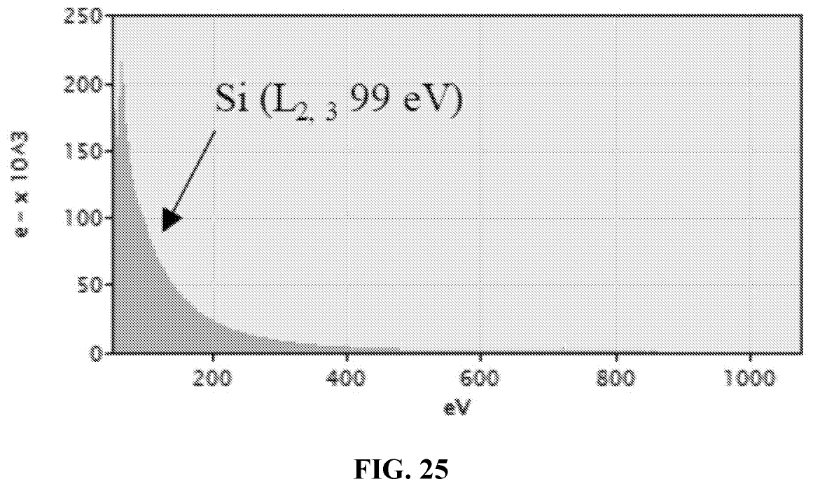

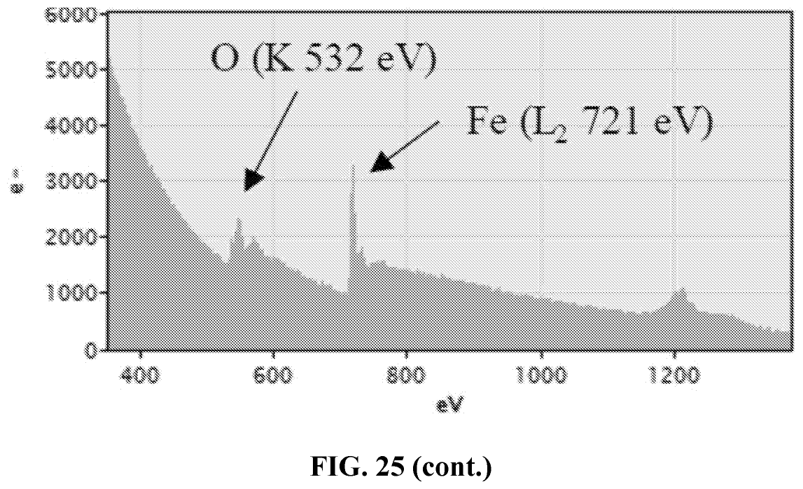

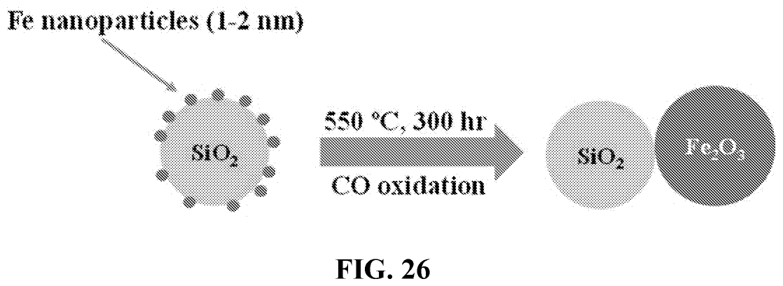

It is also noted that according to the XRD analysis, the Fe₂O₃ crystal size was around 30 nm for Fe/SiO₂ sample after 300 hr reaction, and it was much larger than that of as-prepared Fe NPs (1.5 nm). It indicates that Fe NPs aggregated during the long-term reaction process. In order to verify this, HRTEM and EDX mapping were applied for the Fe/SiO₂ catalyst after 300 hr of CO oxidation reaction. As shown in FIG. 24, there were some large particles (>30 nm) and they were aggregated Fe₂O₃ NPs since only Fe and O were detected based on electron energy loss spectroscopy (EELS) results (FIG. 25) and no Si was detected. It is noted that the CO conversion was still 100% though Fe NPs aggregated during the long-term CO oxidation process. This can be explained that at the beginning of the long-term stability test, only a limited number of Fe₂O₃ active sites were used to catalyze CO oxidation; as the reaction time went on, more Fe converted to Fe₂O₃ and involved in catalytic CO oxidation, though Fe NPs aggregated gradually. In addition, the BET surface area of Fe/SiO₂ after 300 hr of CO oxidation was higher than that of as-prepared Fe/SiO₂ sample (Table 4), which could be due to the fact that Fe NPs aggregated and became large NPs during the long-term stability test, and thereby some surface area of SiO₂ which were occupied by Fe NPs previously were released, as shown in FIG. 26. So, the surface area of the sample increased and the total number of Fe₂O₃ active sites would be enough for the catalytic reaction. Thus, the Fe/SiO₂ catalyst showed good stability of catalytic performance. As is known, a mix of precious metal (Pd, Pt, and Rh) is the most widely used catalyst in catalytic convertor of vehicles that converts toxic gases and pollutants in exhaust gas to less toxic pollutants by catalyzing a redox reaction (an oxidation and a reduction reaction). Among them, Pd and Pt are mainly applied for catalytic oxidization of CO and unburnt hydrocarbons. Based on the results presented in this disclosure, the Fe/SiO₂ catalyst disclosed herein has potential to substitute Pd and Pt to catalyze CO oxidation. Since Fe is an earth-abundant element and is much cheaper than noble metals (Pd and Pt), it will significantly reduce the cost if Fe catalyst can be used in emissions control and auto industry in the future.

In summary of the foregoing example, highly dispersed Fe NPs were deposited on SiO₂ NPs by ALD successfully, and the average size of the Fe NPs was 1.5 nm. The Fe/SiO₂ catalyst showed a high activity and an excellent long-term stability at high temperature in the reaction of CO oxidation. Fe₂O₃ played a vital role in catalytic CO oxidation. Due to their high efficiency, excellent stability, and low cost, it is a potential catalyst for CO removal in large-scale applications, such as treatment of exhaust gas.

EXAMPLE 9. Preparation of Fe/SiO₂. Fe ALD was carried out using ferrocene (99% purity, Alfa Aesar) and hydrogen (H₂, 99.9%, Airgas) as precursors in a fluidized bed reactor. All of the chemicals were used as received without any treatment. Total five cycles of Fe ALD were applied on SiO₂ nanoparticles (NPs) (20-30 nm). For a typical run, 3 g SiO₂ NPs was loaded into the reactor. The reaction temperature was 400° C. During the ALD process, the solid ferrocene was loaded into a heated bubbler and carried by nitrogen (N₂, 99.9%, Airgas) into the reactor. Ferrocene and H₂ were fed separately. The particle substrates were fully fluidized and gas flow rates were controlled by mass flow controllers. The reactor was also subjected to vibration from vibrators to improve the quality of particle fluidization during the ALD process (see: Patel, R. L.; et al., Ceramics International 2015, 41, 2240-2246; Wang, X.; et al., Catalysis Letters 2016, 146, 2606-2613). N₂ was used as a flush gas to remove unreacted precursors and any byproducts during the reaction. A typical coating cycle involved the following steps: ferrocene dose (900 s), N₂ purge (900 s), evacuation (10 s); H₂ dose (1200 s), N₂ purge (900 s), evacuation (10 s).

Characterization. The Fe mass fractions of Fe/SiO₂ NPs were measured by inductively coupled plasma atomic emission spectroscopy (ICP-AES). Raman spectra of SiO₂ NPs and Fe/SiO₂ samples were obtained using a Horiba-Jobin Yvon LabRam spectrometer. A Quantachrome Autosorb-1 was used to obtain nitrogen adsorption and desorption isotherms of SiO₂ NPs at −196° C. The BET surface areas of the SiO₂ NPs and Fe/SiO₂ samples before and after CO oxidation tests were calculated using the BET method in a relative pressure range of 0.05-0.25. TEM and EELS analysis of the Fe/SiO₂ catalyst before and after CO oxidation reaction was characterized by a FEI Tecnai F30 TEM operated at 300 kV. Samples were directly supported on holey-carbon Cu grids. At least 200 particles were randomly measured to determine the average diameter of Fe NPs.

H₂-temperature programmed reduction (H₂-TPR) was applied to analyze the Fe/SiO₂ catalyst. TPR experiments were performed using a Micromeritics AutoChem 2920 instrument. For a typical run, 50 mg of sample was loaded in a U-tube quartz reactor. Then, the sample was reduced in a flow of H₂—Ar mixture (containing 10 vol. % H₂), and the sample temperature increased to 900° C. at a rate of 10° C./min and held at 900° C. for 30 min. TPR patterns were obtained by recording the thermal conductivity detector (TCD) signal with respect to temperature.

The crystal structure of Fe/SiO₂ sample before and after CO oxidation was detected by XRD with filtered Cu Kα radiation (λ=1.5406 Å). The scanning range was 20 from 20° to 80°, with a scanning rate of 0.025°/s. The Scherrer equation was applied to estimate the average crystallite sizes of Fe/SiO₂ samples:

$$D = \frac{K λ}{B cos θ} ,$$

where B is the half-height width of the diffraction peak of anatase, K=0.89 is a coefficient, θ is the diffraction angle, λ is the X-ray wavelength corresponding to the Cu Kα irradiation (1.5406 Å) and D is the average crystallite size of the powder sample.

The XPS spectra of Fe/SiO₂ samples before and after CO oxidation reactions were recorded with a Kratos Axis 165 X-ray photoelectron spectrometer using a monochromatic Al Kα radiation (hv=1486.6 eV), at a take-off angle of 0°. The survey scan spectra and Fe 2p core level spectra were recorded at a pass energy of 160 eV and 20 eV, respectively. All binding energy values were corrected to C 1s signal (284.5 eV).

General procedure for CO oxidation. The CO oxidation reactions were carried out in a fixed bed quartz reactor with quartz wool supporting the catalysts. In a typical run, 50 mg Fe/SiO₂ or SiO₂ NPs was used for the reactions. A gas mixture, with 4% CO, 4% O₂, and 92% N₂ of a total flow rate of 50 mL/min (sccm), was introduced into the reactor for CO oxidation reaction. MKS® mass flow controllers were used to control the gas flow rate. Reaction temperature ranged from 200° C. to a temperature at which the CO conversion reached 100%. Reaction products were analyzed by an online gas chromatograph (SRI 8610C) equipped with a 6 foot HAYESEP D column, a 6 foot MOLECULAR SIEVE 13× column, and a FID detector. After reaction, the Fe/SiO₂ catalyst was directly used for the following cycling tests when applicable. In addition, CO oxidation reactions over the Fe/SiO₂ catalyst were performed with different molar ratios of CO to O₂ (1:1, 1:5, and 1:10) to investigate the effect of oxygen amount on the reaction. Moreover, in order to verify the long-term stability of the Fe/SiO₂ sample, the CO oxidation reaction over Fe/SiO₂ (50 mg) was performed for more than 300 hrs at 550° C.

As can be easily understood from the foregoing, the basic concepts of the present invention may be embodied in a variety of ways. The invention involves numerous and varied embodiments of producing and characterizing the compositions described herein. As such, the particular embodiments or elements of the invention disclosed by the description or shown in the figures or tables accompanying this application are intended to be exemplary of the numerous and varied embodiments generically encompassed by the invention or equivalents encompassed with respect to any particular element thereof. In addition, the specific description of a single embodiment or element of the invention may not explicitly describe all embodiments or elements possible; many alternatives are implicitly disclosed by the description and figures.

It should be understood that each element of a composition or an apparatus or each step of a method may be described by a composition term, an apparatus term or method term. Such terms can be substituted where desired to make explicit the implicitly broad coverage to which this invention is entitled. As but one example, it should be understood that all steps of a method may be disclosed as an action, a means for taking that action, or as an element which causes that action. Similarly, each element of a composition or apparatus may be disclosed as the physical element or the action which that physical element facilitates.

In addition, as to each term used, it should be understood that unless its utilization in this application is inconsistent with such interpretation, common dictionary definitions should be understood to be included in the description for each term as contained in the Random House Webster's Unabridged Dictionary, second edition, each definition hereby incorporated by reference.

All numeric values herein are assumed to be modified by the term “about”, whether or not explicitly indicated. For the purposes of the present invention, ranges may be expressed as from “about” one particular value to “about” another particular value. When such a range is expressed, another embodiment includes from the one particular value to the other particular value. The recitation of numerical ranges by endpoints includes all the numeric values subsumed within that range. For example, a numerical range of one to five includes the numeric values 1, 1.5, 2, 2.75, 3, 3.80, 4, 5, and so forth. It will be further understood that the endpoints of each of the ranges are significant both in relation to the other endpoint and independently of the other endpoint. When a value is expressed as an approximation by use of the antecedent “about,” it will be understood that the particular value forms another embodiment. The term “about” generally refers to a range of numeric values that one of skill in the art would consider equivalent to the recited numeric value or having the same function or result. Similarly, the antecedent “substantially” means largely, but not wholly, the same form, manner or degree and the particular element will have a range of configurations as a person of ordinary skill in the art would consider as having the same function or result. When a particular element is expressed as an approximation by use of the antecedent “substantially,” it will be understood that the particular element forms another embodiment.

It is to be understood that, as used herein, the grammatical conjunction “and/or” refers throughout to either or both of the stated possibilities.

The use of the term “or” in the claims is used to mean “and/or” unless explicitly indicated to refer to alternatives only or the alternatives are mutually exclusive, although the disclosure supports a definition that refers to only alternatives and “and/or.”

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

Moreover, for the purposes of the present invention, the term “a” or “an” entity refers to one or more of that entity unless otherwise limited. As such, the terms “a” or “an”, “one or more” and “at least one” can be used interchangeably herein.

As used herein, the term “composition” generally refers to any product comprising the specified ingredients in the specified amounts, as well as any product which results, directly or indirectly, from combinations of the specified ingredients in the specified amounts. It is to be understood that the compositions described herein may be prepared from isolated compounds described herein or from salts, solutions, hydrates, solvates, and other forms of the compounds described herein. It is also to be understood that the compositions may be prepared from various amorphous, non-amorphous, partially crystalline, crystalline, and/or other morphological forms of the compounds described herein. It is also to be understood that the compositions may be prepared from various hydrates and/or solvates of the compounds described herein. Accordingly, such compositions that recite compounds described herein are to be understood to include each of, or any combination of, the various morphological forms and/or solvate or hydrate forms of the compounds described herein.

For the purpose of this invention, it is to be understood that terms such as “gel and/or aerogel composition”, “gel and/or aerogel material”, “gel and/or aerogel”, and related terms used herein, may be used interchangeably, unless clearly indicated by the context.

The background section of this patent application provides a statement of the field of endeavor to which the invention pertains. This section may also incorporate or contain paraphrasing of certain United States patents, patent applications, publications, or subject matter of the claimed invention useful in relating information, problems, or concerns about the state of technology to which the invention is drawn toward. It is not intended that any United States patent, patent application, publication, statement or other information cited or incorporated herein be interpreted, construed, or deemed to be admitted as prior art with respect to the invention.

The claims set forth in this specification are hereby incorporated by reference as part of this description of the invention, and the applicants expressly reserve the right to use all of or a portion of such incorporated content of such claims as additional description to support any of or all of the claims or any element or component thereof, and the applicants further expressly reserve the right to move any portion of or all of the incorporated content of such claims or any element or component thereof from the description into the claims or vice-versa as necessary to define the matter for which protection is sought by this application or by any subsequent application or continuation, division, or continuation-in-part application thereof, or to obtain any benefit of reduction in fees pursuant to, or to comply with the patent laws, rules, or regulations of any country or treaty, and such content incorporated by reference shall survive during the entire pendency of this application including any subsequent continuation, division, or continuation-in-part application thereof or any reissue or extension thereon.

Additionally, the claims set forth in this specification are further intended to describe the metes and bounds of a limited number of the preferred embodiments of the invention and are not to be construed as the broadest embodiment of the invention or a complete listing of embodiments of the invention that may be claimed. The applicants do not waive any right to develop further claims based upon the description set forth above as a part of any continuation, division, or continuation-in-part, or similar application.

While the disclosure has been illustrated and described in detail in the figures and foregoing description, the same is to be considered as illustrative and not restrictive in character, it being understood that only selected embodiments have been shown and described and that all changes, modifications and equivalents that come within the spirit of the disclosures described heretofore and/or defined by the following claims are desired to be protected. It will be apparent to one of ordinary skill in the art that various changes and modifications can be made to the claimed invention without departing from the spirit and scope thereof. Thus, for example, those skilled in the art will recognize, or be able to ascertain, using no more than routine experimentation, numerous equivalents to the specific substances and procedures described herein. In addition, all publications cited herein are indicative of the level of skill in the art and are hereby incorporated by reference in their entirety as if each had been individually incorporated by reference and fully set forth.

What is claimed is:

1. A method for depositing a metal onto a substrate by using ALD in a suitable reactor, to provide a well-dispersed metal/substrate composition, said method comprising one or more of the following steps:
(a) obtaining a premeasured amount of a suitable metal precursor;
(b) obtaining a premeasured amount of a suitable substrate;
(c) making ready an excess amount of one or more suitable precursor gas;
(d) degassing the substrate at a temperature ranging between about 100° C. and about 200° C. for a period of time ranging between about 5 hours and about 15 hours;
(e) loading the degassed substrate into the reactor;
(f) raising the temperature of the reactor to between about 100° C. and about 500° C.;
(g) fluidizing the substrate particles in the reactor by using flowing inert gas;
(h) loading the metal precursor into a bubbler heated to between about 40° C. and about 280° C.;
(i) carrying the metal precursor particles into the reactor by using flowing inert gas;
(j) feeding the one or more precursor gas separately into the reactor through a distributor plate to react with the metal precursor and produce the metal particles;
(k) subjecting the reactor to vibration from vibrators to enhance particle fluidization during the ALD coating process;
(l) continuing the reaction of the metal precursor and the one or more precursor gas in the reactor for a suitable dose time, and for suitable number of cycles, to result in deposition of the metal particles onto the substrate particles;
(m) flushing the reactor with inert gas to remove unreacted metal precursor and precursor gas and any byproducts;
(n) evacuating and cooling to ambient temperature;
(o) obtaining the well-dispersed metal/substrate composition;
wherein the suitable metal precursor and the one or more precursor gas are selected to be reactive with each other to produce metal particles; and wherein the suitable reactor is selected from a fluid bed reactor (FBR) or a viscous flow reactor or any other suitable flow types of reactors known in the art; and wherein said well-dispersed metal/substrate composition comprises metal nanoparticles and/or metal single atoms on said substrate

2. The method of claim 1, wherein the weight ratio of the suitable metal precursor to suitable substrate is in the range between about 0.05 and about 1.

3. The method of claim 2, wherein the weight ratio of the suitable metal precursor to suitable substrate is in the range between about 0.08 and about 0.15.

4. The method of claim 1, wherein in step (d) the degassing temperature is about 150° C.

5. The method of claim 1, wherein in step (d) the degassing period of time is about 10 hours.

6. The method of claim 1, wherein in step (f) the reactor temperature is about 400° C.

7. The method of claim 1, wherein in steps (g) and (i) the gas flow rate is controlled by mass flow controllers.

8. The method of claim 1, wherein in step (h) the bubbler is heated to about 115° C.

9. The method of claim 8, wherein the well-dispersed metal/substrate composition is a metal nanoparticle/substrate composition.

10. The method of claim 8, wherein the well-dispersed metal/substrate composition is a single metal/substrate composition.

11. The method of claim 1, wherein the metal is selected from Fe, Ni, Co, Ru, Rh, Ir, Os, Pt, and Pd.

12. The method of claim 1, wherein the suitable substrate is selected from inorganic non-metallic materials, metal oxides, and carbon materials.

13. The method of claim 12, wherein the suitable substrate is selected from carbon nanotubes (CNTs), SiO₂, TiO₂, alumina, CeO₂, ZnO, ZrO₂, activated carbon, CuO, Fe₂O₃, MgO, CaO, and graphene.

14. The method of claim 13, wherein when the suitable substrate is a carbon nanotubes substrate it is a multi-walled carbon nanotubes substrate.

15. The method of claim 1, wherein when the metal is Fe, Ni, or Co, the suitable metal precursor is ferrocene, nickelocene, or cobaltocene, respectively, and the suitable precursor gas is hydrogen gas.

16. The method of claim 1, wherein when the metal is Ru, the suitable metal precursor is selected from 2,4-(dimethylpentadienyl)(ethylcyclopentadienyl)Ru, tris(2,2,6,6-tetramethyl-3,5-heptanedionato)ruthenium, RuCp₂, Ru(EtCp)₂, (EtCp)Ru(Py), and (MeCp)Ru(Py), and the suitable precursor gas is selected from O₂ gas and O₂/H₂.

17. The method of claim 1, wherein when the metal is Rh, the suitable metal precursor is rhodium (III) acetylacetonate, and the suitable precursor gas is selected from O₂ gas and O₂/H₂.

18. The method of claim 1, wherein when the metal is Ir, the suitable metal precursor is selected from Ir(acac)₃, (EtCp)Ir(COD), (MeCp)Ir(CHD), and IrF₆, and the suitable precursor gas is O₂/H₂.

19. The method of claim 1, wherein when the metal is Os, the suitable metal precursor is OsCp₂, and the suitable precursor gas is O₂/H₂.

20. The method of claim 1, wherein the suitable metal precursor is a mixture of two or more different suitable metal precursors of the same metal.

21. The method of claim 1, wherein the suitable metal precursor is a mixture of two or more different suitable metal precursors of two or more different metals.

22. The method of claim 1, wherein the suitable substrate is a mixture of two or more different suitable substrates.

23. The method of claim 1, wherein the metal in the obtained well-dispersed metal/substrate composition is selected from nanoparticulate metal, sub-nanoparticulate metal, and single metal atoms.

24. The method of claim 1, wherein the metal in the obtained well-dispersed metal/substrate composition has a higher density than metal densities obtained in other published methods.

25. The method of claim 1, wherein the metal in the obtained well-dispersed metal/substrate composition has well-defined and uniform dispersion on the substrate, whose dispersion ranges between 70% and 100%.

26. The method of claim 1, wherein the obtained well-dispersed metal/substrate composition exhibits more than six-fold enhancement of catalytic activity in the photocatalytic degradation of methylene blue over pure substrate alone.

27. The method of claim 26, wherein the metal is Fe and the substrate is TiO₂.

28. The method of claim 1, wherein the obtained well-dispersed metal/substrate composition exhibits catalytic activity towards CO oxidation that is more than two orders of magnitude higher than that of reported literature catalysts.

29. The method of claim 28, wherein the metal is Fe and the substrate is SiO₂.

30. A composition comprising metal nanoparticles and/or metal single atoms on a substrate, said composition obtained by a novel method for depositing a metal onto a substrate by using ALD in a suitable reactor, wherein said method comprises one or more of the following steps:
(a) obtaining a premeasured amount of a suitable metal precursor;
(b) obtaining a premeasured amount of a suitable substrate;
(c) making ready an excess amount of one or more suitable precursor gas;
(d) degassing the substrate at a temperature ranging between about 100° C. and about 200° C. for a period of time ranging between about 5 hours and about 15 hours;
(e) loading the degassed substrate into the reactor;
(f) raising the temperature of the reactor to between about 100° C. and about 500° C.;
(g) fluidizing the substrate particles in the reactor by using flowing inert gas;
(h) loading the metal precursor into a bubbler heated to between about 40° C. and about 280° C.;
(i) carrying the metal precursor particles into the reactor by using flowing inert gas;
(j) feeding the one or more precursor gas separately into the reactor through a distributor plate to react with the metal precursor and produce the metal particles;
(k) subjecting the reactor to vibration from vibrators to enhance particle fluidization during the ALD coating process;
(l) continuing the reaction of the metal precursor and the one or more precursor gas in the reactor for a suitable dose time, and for suitable number of cycles, to result in deposition of the metal particles onto the substrate particles;
(m) flushing the reactor with inert gas to remove unreacted metal precursor and precursor gas and any byproducts;
(n) evacuating and cooling to ambient temperature;
(o) obtaining the composition comprising metal nanoparticles and/or metal single atoms on the substrate;
wherein the suitable metal precursor and the one or more precursor gas are selected to be reactive with each other to produce metal particles; and wherein the suitable reactor is selected from a fluid bed reactor (FBR) or a viscous flow reactor or any other suitable flow types of reactors known in the art.

31. The composition of claim 30, wherein in the novel method the weight ratio of the suitable metal precursor to suitable substrate is in the range between about 0.05 and about 1.

32. The composition of claim 31, wherein in the novel method the weight ratio of the suitable metal precursor to suitable substrate is in the range between about 0.08 and about 0.15.

33. The composition of claim 30, wherein in step (d) of the novel method the degassing temperature is about 150° C.

34. The composition of claim 30, wherein in step (d) of the novel method the degassing period of time is about 10 hours.

35. The composition of claim 30, wherein in step (f) of the novel method the reactor temperature is about 400° C.

36. The composition of claim 30, wherein in steps (g) and (i) of the novel method the gas flow rate is controlled by mass flow controllers.

37. The composition of claim 30, wherein in step (h) of the novel method the bubbler is heated to about 115° C.

38. The composition of claim 30, wherein the obtained composition is a metal nanoparticle/substrate composition.

39. The composition of claim 30, wherein the obtained composition is a metal single atom/substrate composition.

40. The composition of claim 30, wherein the metal is selected from Fe, Ni, Co, Ru, Rh, Ir, Os, Pt, and Pd.

41. The composition of claim 30, wherein in the novel method the suitable substrate is selected from inorganic non-metallic materials, metal oxides, and carbon materials.

42. The composition of claim 41, wherein in the novel method the suitable substrate is selected from carbon nanotubes (CNTs), SiO₂, TiO₂, alumina, CeO₂, ZnO, ZrO₂, activated carbon, CuO, Fe₂O₃, MgO, CaO, and graphene.

43. The composition of claim 42, wherein in the novel method when the suitable substrate is a carbon nanotubes substrate it is a multi-walled carbon nanotubes substrate.

44. The composition of claim 30, wherein in the novel method when the metal is Fe, Ni, or Co, the suitable metal precursor is ferrocene, nickelocene, or cobaltocene, respectively, and the suitable precursor gas is hydrogen gas.

45. The composition of claim 30, wherein in the novel method when the metal is Ru, the suitable metal precursor is selected from 2,4-(dimethylpentadienyl)(ethylcyclopentadienyl)Ru, tris(2,2,6,6-tetramethyl-3,5-heptanedionato)ruthenium, RuCp₂, Ru(EtCp)₂, (EtCp)Ru(Py), and (MeCp)Ru(Py), and the suitable precursor gas is selected from O₂ gas and O₂/H₂.

46. The composition of claim 30, wherein in the novel method when the metal is Rh, the suitable metal precursor is rhodium (III) acetylacetonate, and the suitable precursor gas is selected from O₂ gas and O₂/H₂.

47. The composition of claim 30, wherein in the novel method when the metal is Ir, the suitable metal precursor is selected from Ir(acac)₃, (EtCp)Ir(COD), (MeCp)Ir(CHD), and IrF₆, and the suitable precursor gas is O₂/H₂.

48. The composition of claim 30, wherein in the novel method when the metal is Os, the suitable metal precursor is OsCp₂, and the suitable precursor gas is O₂/H₂.

49. The composition of claim 30, wherein in the novel method the suitable metal precursor is a mixture of two or more different suitable metal precursors of the same metal.

50. The composition of claim 30, wherein in the novel method the suitable metal precursor is a mixture of two or more different suitable metal precursors of two or more different metals.

51. The composition of claim 30, wherein in the novel method the suitable substrate is a mixture of two or more different suitable substrates.

52. The composition of claim 30, wherein the metal in the obtained composition is selected from nanoparticulate metal, sub-nanoparticulate metal, and single metal atoms.

53. The composition of claim 30, wherein the metal in the obtained composition has a higher density than metal densities obtained in previously published methods.

54. The composition of claim 30, wherein the metal in the obtained composition has well-defined and uniform dispersion on the substrate, whose dispersion ranges between 70% and 100%.

55. The composition of claim 30, wherein the obtained composition exhibits more than six-fold enhancement of catalytic activity in the photocatalytic degradation of methylene blue over pure substrate alone.

56. The composition of claim 55, wherein the metal is Fe and the substrate is TiO₂.

57. The composition of claim 30, wherein the obtained composition exhibits catalytic activity towards CO oxidation that is more than two orders of magnitude higher than that of previously reported literature catalysts.

58. The composition of claim 57, wherein the metal is Fe and the substrate is SiO₂.
